(19) United States
(12) Patent Application Publication
(10) Pub. No.: US 2026/0190710 A1
(43) Pub. Date: Jul. 2, 2026

(54) Display Device

(71) Applicant: LG Display Co., Ltd., Seoul (KR)

(72) Inventors: Jeon Phill Han, Paju-si, Gyeonggi-do (KR); Seung Han Paek, Paju-si, Gyeonggi-do (KR); Hyun Jin An, Paju-si, Gyeonggi-do (KR); Nam Woo Kim, Paju-si, Gyeonggi-do (KR)

(21) Appl. No.: 19/402,072

(22) Filed: Nov. 26, 2025

(30) Foreign Application Priority Data
Dec. 26, 2024 (KR) 10-2024-0196513

(51) Int. Cl. H10K 59/131; H10H 29/24; H10H 29/49; H10K 59/95

(52) U.S. Cl. CPC H10K 59/131; H10H 29/24; H10H 29/49; H10K 59/95

(57) ABSTRACT

A display device disclosed herein includes a substrate including a first area, a second area and a third area spaced apart from each other by a first groove and a second groove; a circuit layer arranged on the first area and including a transistor; a first pad arranged on the second area; a second pad arranged on the third area; and a plurality of connection wires and a plurality of bending wires connecting the circuit layer, the first pad and the second pad, wherein a chip is arranged on the first pad.

### CROSS-REFERENCE TO RELATED APPLICATIONS

This application claims priority under 35 U.S.C. § 119(a) to the Republic of Korea Patent Application No. 10-2024-0196513, filed on December, 26, 2024, the entire contents of which is are hereby expressly incorporated by reference into the present application.

### TECHNICAL FIELD

Embodiments relate to a display panel and a display device including the same.

### BACKGROUND

Display devices have been widely used as display screens of various electronic devices such as a mobile communication terminal, an electronic notebook, an electronic book, a portable multimedia player (PMP), a navigation device, an ultra-mobile personal computer (UMPC), a mobile phone, a tablet personal computer (PC), a watch phone, an electronic pad, a wearable device, a portable information device, a vehicle control display device, a television, a notebook, a monitor, and the like.

Recently, research and development on a display device capable of implementing a maximum screen size by reducing a bezel area where an image is not displayed at the same display panel size have been conducted.

As the display's bending area is bent, the bending area, composed of organic films and wires, may be formed in a C-shape with a predetermined radius of curvature. However, in the case of displays that include a C-shaped bending area, there is a structural limit to reducing the non-display area (or bezel area), which does not display an image, by the bending area's radius of curvature.

Therefore, there is a demand for a display panel and a display device including the same that allow the non-display area (or bezel area) to be structurally reduced and the rigidity in the bending area to be improved.

### SUMMARY

Embodiments of the present specification provide a display panel and a display device including the same in which a narrow bezel may be implemented by structurally reducing a non-display area (or bezel area), which does not display an image, through use of two grooves formed in a substrate.

Embodiments of the present specification provide a display panel and a display device including the same in which the rigidity may be structurally improved by arranging a portion of a substrate between two grooves.

Embodiments of the present specification provide a display panel and a display device including the same that may use some configuration arranged in a display area as an anti-etching layer to simplify the manufacturing process.

Embodiments of the present specification provide a display panel and a display device including the same that may use a bending wire arranged in a bending area to reduce or prevent damage to or reduce or minimize the possibility of damage to a connection wire due to bending.

Embodiments of the present specification provide a display panel and a display device including the same that may reduce or minimize resistance differences among a plurality of connection wires.

The objectives to be solved by the embodiments of this specification are not limited to the objectives mentioned above, and other objectives not mentioned will be clearly understood by those skilled in the art from the following descriptions.

A display device according to an embodiment of the present specification includes a substrate including a first area, a second area and a third area spaced apart from each other by a first groove and a second groove; a circuit layer arranged on the first area and including a transistor; a first pad arranged on the second area; a second pad arranged on the third area; and a plurality of connection wires and a plurality of bending wires connecting the circuit layer, the first pad and the second pad, wherein a chip is arranged on the first pad.

A display device according to an embodiment of the present specification includes a display area in which an image is implemented, and a non-display area surrounding at least a portion of the display area, wherein the non-display area includes a first non-display area, a bending area including a groove, and a second non-display area, wherein a first pad, where a chip is arranged, is arranged in the bending area, and wherein a second pad, to which a circuit board is connected, is arranged in the second non-display area overlapping with the first non-display area by bending of the bending area.

A display device according to an embodiment of the present specification includes a display area in which an image is implemented, and a non-display area surrounding at least a portion of the display area, wherein the non-display area includes a first non-display area, a bending area including two grooves, and a second non-display area, wherein a first pad, where a chip is arranged, is arranged between the two grooves, and wherein a second pad, to which a circuit board is connected, is arranged in the second non-display area overlapping with the first non-display area by bending of the bending area.

According to the present specification, a narrow bezel may be implemented by structurally reducing the non-display area (or bezel area), which does not display an image, through use of the two grooves formed in the substrate.

According to the present specification, the rigidity may be structurally improved by arranging a portion of the substrate between the two grooves.

According to the present specification, some configurations arranged in the display area may be used as an anti-etching layer.

According to the present specification, the rigidity of the substrate may be maintained by processing the substrate of a glass material through an etching process.

According to the present specification, damage to the bending wire arranged in the bending area may be reduced or prevented by using a planarization layer of an organic material during etching the substrate formed of the glass material.

According to the present specification, the bending wire arranged in the bending area may reduce or prevent damage to or reduce or minimize the possibility of damage to the connection wire due to bending.

According to the present specification, the bending wire may be protected by a pattern layer and a protective layer arranged on the bending wire. Accordingly, the lifespan of the display panel may be improved, thereby reducing greenhouse gases in the production process.

According to the present specification, by providing an embodiment showing various arrangement relationships for connection wires, the design freedom of connection wires may be improved while minimizing resistance differences among the plurality of connection wires.

Various useful advantages and effects of the embodiments of this specification are not limited to the above-described contents, and effects which are not described above will be clearly understood by those skilled in the art from the following descriptions.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a perspective view illustrating a display device according to an embodiment of the present specification.

FIG. 2 is a plan view illustrating the display device according to the embodiment of the present specification.

FIG. 3 is a cross-sectional view taken along line I-I′ in FIG. 2.

FIG. 4A is an enlarged view illustrating area A of FIG. 3.

FIG. 4B is an enlarged view illustrating area B of FIG. 3.

FIG. 5 is a view illustrating a neutral plane according to bending.

FIG. 6 is a view illustrating a coating layer arranged in the display panel according to the embodiment of the present specification.

FIG. 7 is a view illustrating a bent appearance of the display device according to the embodiment of the present specification.

FIG. 8 is a view illustrating a thermal conductive member of the display device according to the embodiment of the present specification.

FIG. 9 is a view illustrating one embodiment of connection wire arranged in the display panel according to an embodiment of the present specification.

FIG. 10 is an enlarged view of area C in FIG. 9.

FIG. 11 is a view illustrating one embodiment of a connection wire arranged in the display panel according to the embodiment of the present specification.

FIG. 12 is an enlarged view of area D in FIG. 11.

FIG. 13 is a view illustrating one embodiment of a connection wire arranged in the display panel according to the embodiment of the present specification.

FIG. 14 is an enlarged view of area E in FIG. 13.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising”, “including”, “having” and “consisting of” used herein are generally intended to allow other components to be added unless the terms are used with the term “only”. References to the singular shall be construed to include the plural unless expressly stated otherwise.

In interpreting a component, it is interpreted to include an error range even if there is no separate description.

When describing a positional or interconnected relationship between two components, such as “on top of”, “above”, “below”, “next to”, “connect or couple with”, “crossing”, “intersecting” etc., one or more other components may be interposed between them unless “immediately” or “directly” is used.

When describing a temporal contextual relationship is described, such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Throughout the specification, the same reference numerals refer to the same component.

A display device according to an embodiment in this disclosure may include a display device itself in a narrow sense, an application product including a display in a narrow sense, or even a set device that is an end-consumer device.

The display device according to the embodiment of the present specification may be implemented with a liquid crystal display device (LCD), a plasma display panel device (PDP), a field emission display device (FED), an electroluminescence display device (ELD), an organic light emitting diodes (OLED), a quantum dot display, a micro light emitting diode (micro LED) display, or the like. For example, the display area DA of the display device according to the embodiment of the present specification is exemplified by a liquid crystal display utilizing a liquid crystal layer, but not necessarily limited thereto. For example, the display area DA may be implemented with any one of OLED, QLED, and Micro LED.

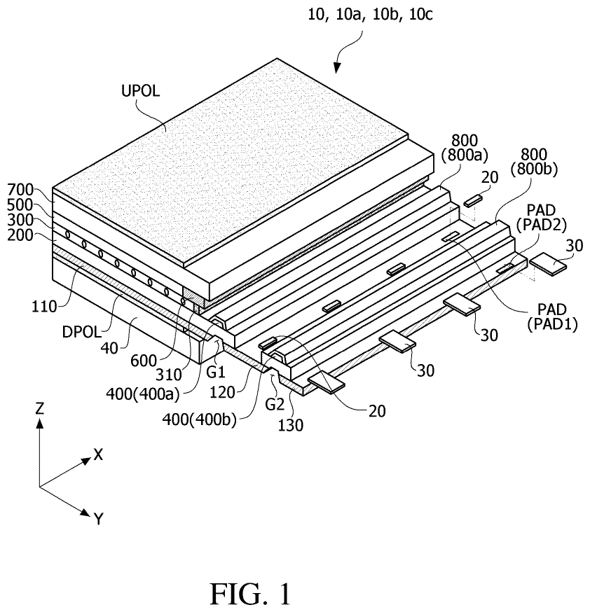

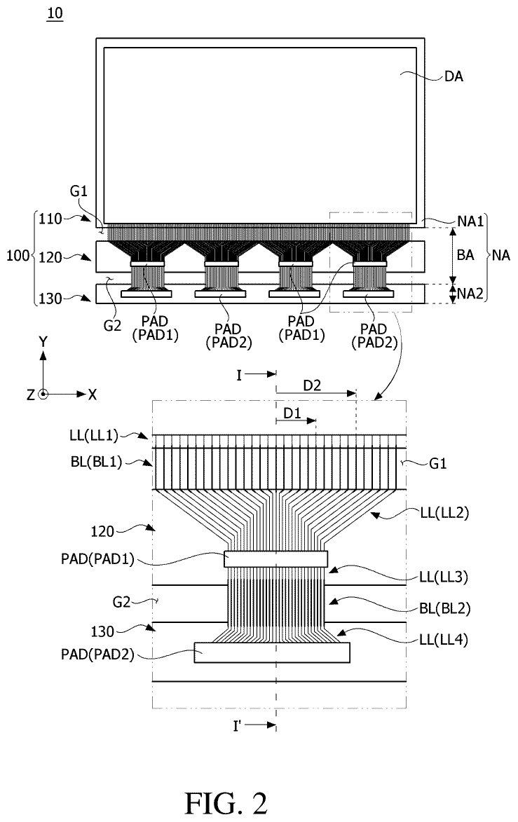

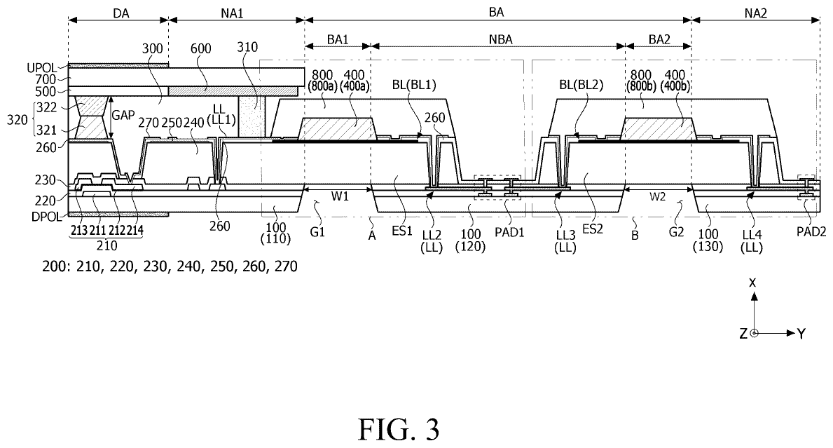

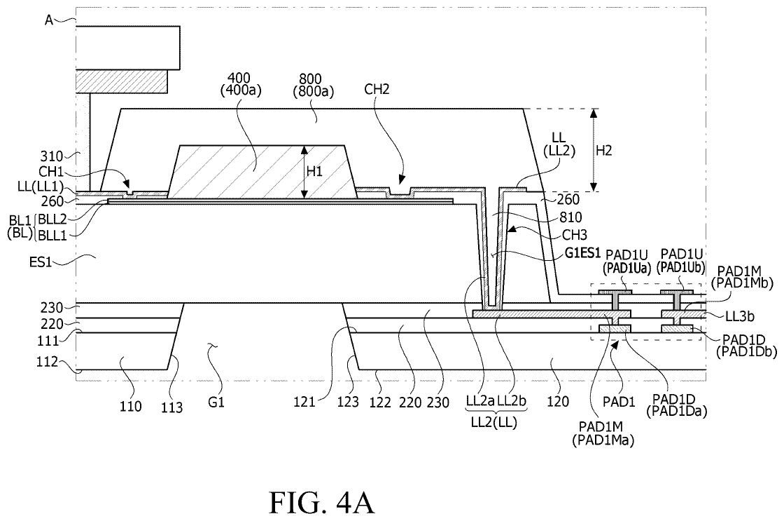

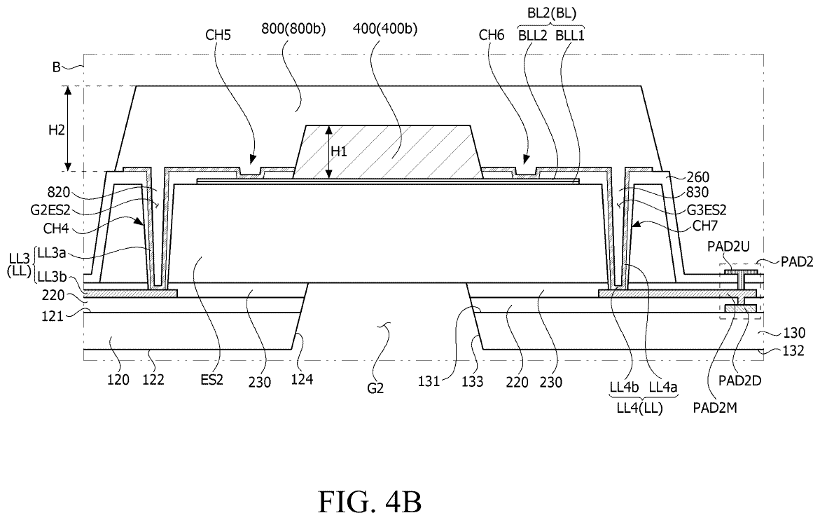

FIG. 1 is a perspective view illustrating a display device according to an embodiment of the present specification. FIG. 2 is a plan view illustrating a display panel according to an embodiment of the present specification. FIG. 3 is a cross-sectional view taken along line I-I′ in FIG. 2. FIGS. 4A and 4B are enlarged views of some areas in FIG. 3. For example, FIG. 4A is an enlarged view illustrating area A of FIG. 3. FIG. 4B is an enlarged view illustrating area B of FIG. 3. Here, the line I-I′ may be an imaginary line passing through the center of the X-axis in the direction of the first pad PAD1.

Referring to FIGS. 1 to 3, the display device according to the embodiment of the present specification may include a display panel 10 including a first groove G1 and a second groove G2, a chip 20 connected to a first pad PAD1 of the display panel 10, and a circuit board 30 connected to a second pad PAD2 of the display panel 10. In the display area DA of the display panel 10, an input image may be visually reproduced. Here, the input image may be implemented with any one of OLED, QLED, Micro LED and LCD, but will be described hereinafter as being implemented with a liquid crystal display using a liquid crystal layer 300.

The display device according to one embodiment of the present specification may include a light source 40 that emits light toward the liquid crystal layer 300 of the display panel 10. In addition, an input image may be visually reproduced on the display panel 10. The light source 40 may be a backlight unit.

The display panel 10 may include a display area DA where an image is displayed and a non-display area NA where no image is displayed. The display panel 10 may be a panel having a rectangular structure having a width in an X-axis direction, a length in a Y-axis direction, and a thickness in a Z-axis direction. In such a case, the width and length of the display panel 10 may be set to various design values depending on the application field of the display device. The X-axis direction may mean a width direction, a row direction, or a horizontal direction, the Y-axis direction may mean a length direction, a column direction, or a vertical direction, and the Z-axis direction may mean an up-down direction, a vertical direction, or a thickness direction. The X-axis direction, the Y-axis direction, and the Z-axis direction may be perpendicular to one another, but may also mean different directions not perpendicular to one another. Therefore, each of the X-axis direction, the Y-axis direction, and the Z-axis direction may be described as any one of a first direction, a second direction, and a third direction. A plane extended in the X-axis direction and the Y-axis direction may mean a horizontal plane.

The non-display area NA may include a first non-display area NA1, a bending area BA, and a second non-display area NA2.

The first non-display area NA1 may be an area surrounding at least a part of the display area DA.

The bending area BA may be an area adjacent to at least one of a plurality of sides of the first non-display area NA1 and may be a bendable area. The display panel 10 may be easily bent through use of the first groove G1 and the second groove G2 arranged in the bending area BA. In this case, a first pad PAD1 may be arranged in the bending area BA. As such, since the first pad PAD1 is arranged in the bending area BA rather than the second non-display area NA2, the size of the non-display area that does not display an image may be structurally reduced.

Referring to FIGS. 2 and 3, the bending area BA is located between the first non-display area NA1 and the second non-display area NA2, and various structures such as organic layer, inorganic layer and wire arranged in the bending area BA may be bent. For example, various structures such as organic layer, inorganic layer and wire overlapping with the first groove G1 and the second groove G2 may be bent. In this case, a second area 120 of a substrate 100 arranged between the first groove G1 and the second groove G2 may not be bent.

Since the display panel 10 according to the embodiment of the present specification includes the second area 120 of the substrate 100 that remains flat, the radius of curvature at the bending area BA may be reduced compared to a display panel that is bent through use of a single groove. For example, the display panel 10 according to the embodiment of the present specification may include two bending areas BA1 and BA2 that are bent corresponding to the first groove G1 and the second groove G2 that are spaced apart from each other. And, since the second area 120 of the substrate 100 that remains flat is arranged between the first groove G1 and the second groove G2, the radius of curvature of each of the two bending areas BA1 and BA2 may be formed smaller than the radius of curvature of the display panel that is bent through use of the single groove. In this case, the width of the groove arranged in the display panel that is bent through use of the single groove may be equal to the sum of the width of the first groove G1, the width of the second area 120 and the width of the second groove G2, but is not necessarily limited thereto.

As such, since the display panel 10 according to the embodiment of the present specification includes the second area 120 of the substrate 100 arranged between the first groove G1 and the second groove G2, this may reduce the non-display area NA visible in the Z-axis direction when the display panel 10 is bent, so that a narrow bezel may be implemented.

The second non-display area NA2 may be an area adjacent to at least one of the plurality of sides of the bending area BA, and the second pad PAD2 may be arranged in the second non-display area NA2. For example, the bending area BA may be in a bent state from a flat state, and the remaining areas of the substrate 100 other than the bending area BA may be in a flat state. As the bending area BA is bent, the second non-display area NA2 may be located above the back surface of the display area DA to overlap with it.

The chip 20 may be connected to the display panel 10 via the first pad PAD1.

The chip 20 may include drive circuit. For example, the chip 20 may be a drive IC. The drive IC may be connected to data lines to supply a voltage of a data signal to the data lines. Further, the drive IC may include a timing controller.

The circuit board 30 may be a flexible printed circuit board and may be connected to the display panel 10 through the pad portion PAD.

The liquid crystal layer 300 (FIG. 1), etc., of the display area DA may be driven by receiving signals from one or more circuit boards 30 through the wires of the display area DA and the connection wires LL of the non-display area NA. For example, the wires of the display area DA may be wires for transmitting signals output from the chip 20 and/or the circuit board 30 to the liquid crystal layer 300, etc., of the display area DA together with a plurality of connection wires LL.

When only the plurality of connection wires LL is arranged in the bending area BA, a part of the plurality of connection wires LL may also be bent as the bending area BA is bent. Therefore, stress may be concentrated on a part of the bent connection wires LL, and cracks may occur in the connection wires LL due to the stress.

Therefore, when the plurality of connection wires LL is arranged in the bending area BA, the possibility of damage to the connection wires LL due to cracks, etc. may be considered. For example, in order to reduce or prevent cracks that may occur in the plurality of connection wires LL during the bending of the bending area BA, the connection wire LL may be made of conductive materials having excellent ductility. In addition, the plurality of connection wires LL may be formed in various shapes in order to cope with cracks, etc. For example, at least a part of the plurality of connection wires LL arranged on the bending area BA may have a shape in which conductive patterns having at least one shape among a diamond shape, a rhombus shape, a trapezoidal wave shape, a triangular wave shape, a sawtooth wave shape, a sine wave shape, a circular shape, and an omega (Ω) shape are repeatedly arranged.

The display device according to one embodiment of the present specification may stably connect the plurality of connection wires LL and the wires of the display area DA by using the bending wire BL arranged on the bending area BA.

The plurality of connection wires LL may extend from a plurality of second pad PAD2 of the second non-display area NA2 toward the bending area BA. Further, the plurality of connection wires LL may be electrically connected with the wires of the display area DA via the plurality of bending wires BL, but are not necessarily limited thereto. For example, the bending wire BL may be used as auxiliary wire for the connection wire LL by arranging the bending wire BL to overlap with a portion of the connection wire LL. As a result, even if the connection wire LL is damaged by bending of the display panel 10, a signal applied through the connection wire LL may be transmitted to the wire of the display area DA via the bending wire BL.

Therefore, the connection wire LL arranged on the bending area BA and the bending wire BL may be used to reduce the possibility of failure due to bending of the display panel 10. In this case, the display panel 10 according to the embodiment of the present specification may protect the bending wire BL by means of a pattern layer 400 and a protective layer 800 arranged on the bending wire BL. For example, the bending wire BL including copper (Cu) may oxidize when exposed to air, and the resistance of the oxidized bending wire BL may increase. The pattern layer 400 and the protective layer 800 may reduce or prevent oxidation of the bending wire BL. Thus, the pattern layer 400 and the protective layer 800 may further reduce the possibility of failure of the bending wire BL. Here, the connection wire LL may be a link line. The bending wire BL may be a bending line.

The light source 40 may be arranged below a first area 110 to emit light toward the first area 110. For example, the light source 40 may emit light in the Z-axis direction. More specifically, the light source 40 may emit light toward the liquid crystal layer 300 arranged above the first area 110. Here, the light source 40 may be a backlight unit.

The display panel 10 may be manufactured based on a flexible plastic material such as polyimide or a flexible glass substrate having a thin thickness. For example, the substrate 100 of the display panel 10 may be formed of a transparent glass material in consideration of an etching process.

Referring now to FIGS. 1 to 4 (A and B), the display panel 10 according to an embodiment of the present specification includes the substrate 100 including the first area 110, the second area 120 and a third area 130 spaced apart from each other by the first groove G1 and the second groove G2, a circuit layer 200 arranged on the substrate 100, the liquid crystal layer 300 arranged on the circuit layer 200, the first pad PAD1 arranged on the second area 120 for connection with the chip 20, a second pad PAD2 arranged on the third area 130 for connection to the circuit board 30, and a plurality of connection wires LL and a plurality of bending wires BL. Here, the plurality of connection wires LL and the plurality of bending wires BL may connect the wires of the circuit layer 200, the first pad PAD1 and the second pad PAD2. Further, the circuit layer 200 may include a thin film transistor 210, a gate insulating layer 220, a first interlayer dielectric layer 230, a planarization layer 240, a first electrode 250, a second interlayer dielectric layer 260 and a second electrode 270. The thin film transistor 210 may include a gate electrode 211, an active layer 212, a source electrode 213, and a drain electrode 214.

In addition, the display panel 10 according to the embodiment of the present specification may further include a first anti-etching layer ES1 arranged over the first groove G1 and a second anti-etching layer ES2 arranged over the second groove G2. Here, a planarization layer 240 of the circuit layer 200 may extend to a portion of the bending area BA to be arranged over upper portion the first groove G1. Accordingly, a portion of the planarization layer 240 extending from the first area 110 to the second area 120 to cover the upper portion of the first groove G1 may be provided as a first anti-etching layer ES1. Therefore, during etching of the substrate 100 to form the grooves G1 and G2, a portion of the planarization layer 240 may serve as an etch stopper.

The display panel 10 according to the embodiment of the present specification may further include a pattern layer 400 arranged on the bending wire BL.

In addition, the display panel 10 according to the embodiment of the present specification may further include a color filter layer 500 and a black matrix 600 arranged on the liquid crystal layer 300, a sealant 310 surrounding the liquid crystal layer 300, and at least one column 320 arranged between the color filter layer 500 and the circuit layer 200.

Additionally, the display panel 10 according to the embodiment of the present specification may further include a second substrate 700 arranged on the color filter layer 500 and the black matrix 600. Here, the substrate 100 including the first area 110, the second area 120, and the third area 130 may be the first substrate. The second substrate 700 may be a cover member.

In addition, the display panel 10 according to embodiments of the present specification may further include the protective layer 800 arranged on the pattern layer 400.

In addition, the display panel 10 according to the embodiment of the present specification may further include a lower polarization layer DPOL arranged under the first area 110 and an upper polarization layer UPOL arranged over the second substrate 700. In this case, the lower polarization layer DPOL and the upper polarization layer UPOL may overlap with the color filter layer 500.

The substrate 100 may be made of glass, metal, plastic, or the like, but is not limited thereto. However, substrate 100 may use a glass substrate having a predetermined strength for the etching process for process simplification.

The first substrate 100 may include the first area 110, the second area 120, and the third area 130 separated by a first groove G1 and a second groove G2. The third area 130 may overlap with the first area 110 by bending of the display panel 10.

The first area 110 of the first substrate 100 may be arranged in the display area DA. The second area 120 may be arranged in a bending area BA of the non-display area NA. The third area 130 may be arranged in a second non-display area NA2 of the non-display area NA. Accordingly, the first area 110 may be a display area substrate, the second area 120 may be a bending area substrate, and the third area 130 may be a non-display area substrate.

The first groove G1 and the second groove G2 may be formed in the first substrate 100, and the first substrate 100 may be divided into the first area 110, the second area 120, and the third area 130 by the first groove G1 and the second groove G2.

The first groove G1 and the second groove G2 may be arranged to correspond to bending areas BA of the display panel 10. For example, the bending area BA may include a first bending area BA1, a non-bending area NBA, and a second bending area BA2. Here, the non-bending area NBA may be a flat area.

When the display panel 10 is bent, since the non-bending area NBA is the area corresponding to the second area 120 of the substrate 100, it may remain flat. For example, when the first bending area BA1 and the second bending area BA2 are bent by the first groove G1 and the second groove G2, the second area 120 may be located between the first groove G1 and second groove G2, so that it may remain flat.

As the display panel 10 is bent, the first bending area BA1 and second bending area BA2 of the display panel 10 may have different centers of radius of curvature. Here, the first bending area BA1 is an area corresponding to the first groove G1, which may be bent to have a first radius of curvature upon bending of the display panel 10. Further, the second bending area BA2 is an area corresponding to the second groove G2, which may be bent to have a second radius of curvature upon bending of the display panel 10. In this case, the first radius of curvature and the second radius of curvature may be the same, but is not necessarily limited thereto. Further, the width of the first groove G1 and the width of the second groove G2 in the Y-axis direction may be the same, but is not necessarily limited thereto.

Thus, the display panel 10 according to the embodiment of the present specification may include two bending areas BA1 and BA2 having different centers of the radius of curvature by the second area 120 of the substrate 100, so that it may be bent to have a radius smaller than the radius of curvature in the display panel that is bent through use of the single groove. As a result, this may reduce the non-display area NA visible in the Z-axis direction when bending the display panel 10, thereby implementing the narrow bezel.

The first groove G1 and the second groove G2 may be concavely formed in a lower surface of the first substrate 100. Further, the first groove G1 and the second groove G2 may be formed in a tapered shape, but is not necessarily limited thereto.

The first groove G1 and the second groove G2 may be formed in the first substrate 100 through an etching process. In such a case, a plurality of display panels 10 may be manufactured using a single mother substrate including glass, and a cutting process may be performed to the mother substrate after the etching process to separate into each of the plurality of display panels 10.

The plurality of grooves formed in the mother substrate through the etching process may be formed to correspond to the grooves G1 and G2 in each of the plurality of display panels 10. For example, a plurality of grooves may be formed in the mother substrate by etching a portion of the lower surface of the mother substrate using a patterned mask and an etching solution. Accordingly, a process optimization may be implemented by forming a plurality of grooves corresponding to the grooves G1 and G2 of each of the plurality of display panels 10 in the lower surface side of the mother substrate through a single etching process. Here, nitric acid (HNO₃), hydrofluoric acid (HF), or the like may be used as the etching solution.

When forming the groove G1 and G2 through the etching process, the gate insulating layer 220 and the first interlayer dielectric layer 230 of the circuit layer 200 may be removed together with the mother substrate.

Since the gate insulating layer 220 and the first interlayer dielectric layer 230 are not arranged in the first groove G1 and the second groove G2, damage such as cracks due to stress caused by bending does not occur in the gate insulating layer 220 and the first interlayer dielectric layer 230. For example, even though the gate insulating layer 220 and the first interlayer dielectric layer 230 are made of an inorganic insulating material vulnerable to bending, since the gate insulating layer 220 and the first interlayer dielectric layer 230 are not arranged in the bending area BA, the gate insulating layer 220 and the first interlayer dielectric layer 230 are not damaged due to stress caused by bending. In such a case, since the second interlayer dielectric layer 260 made of an inorganic insulating material is also not arranged in the bending area BA, the second interlayer dielectric layer 260 is not damaged due to stress caused by bending.

Furthermore, since the first substrate 100 made of glass is processed by the etching process to form the groove G1 and G2, a decrease in the rigidity of the glass substrate may be reduced or minimized. Accordingly, the rigidity of the glass substrate may be maintained.

The display panel 10 may include an anti-etching layer ES that serves as an etch stopper to resist the etch solution. For example, the anti-etching layer ES of the display panel 10 may include a first anti-etching layer ES1 arranged over the first groove G1 and a second anti-etching layer ES2 arranged over the second groove G2. In this case, the planarization layer 240 of the circuit layer 200 may extend from the first area 110 to the second area 120 of the substrate 100 to be used as the first anti-etching layer ES1.

The anti-etching layer ES may be made of a material having corrosion resistant (or chemical resistant) to the etching solution used in the etching process. For example, the anti-etching layer ES may include at least one of silicone-based organics, urethane, polyimide, and photoacrylic. Further, the anti-etching layer ES may include at least one of chromium (Cr), aluminum (Al), platinum (Pt), gold (Ag), and nickel (Ni). Here, the material of the anti-etching layer ES may be the same as the material of the planarization layer 240 arranged in the circuit layer 200. For example, the first anti-etching layer ES1 and the second anti-etching layer ES2 may be formed along with the planarization layer 240 of the circuit layer 200 by the same masking process that forms the planarization layer 240 of the circuit layer 200.

Since the anti-etching layer ES may be formed of an organic insulating material having strong corrosion resistance to the etching solution, the etching process is no longer performed by the anti-etching layer ES. Accordingly, the grooves G1 and G2 may be formed by the etching process up to the anti-etching layer ES, so that a portion of the bottom surface of the anti-etching layer ES may be exposed by the grooves G1 and G2. For example, a portion of the bottom surface of the first anti-etching layer ES1 may be exposed by the first groove G1, and a portion of the bottom surface of the second anti-etching layer ES2 may be exposed by the second groove G2.

The anti-etching layer ES is intended to protect a configuration located above the anti-etching layer ES during the process of forming the grooves G1 and G2 in the first substrate 100, and the anti-etching layer ES may have a larger size than areas overlapping with the grooves G1 and G2, or a larger size (or width) than the bending area BA. For example, based on the Y-axis direction, the width of the first anti-etching layer ES1 may be larger than the width W1 of the first groove G1, and the width of the second anti-etching layer ES2 may be larger than the width W2 of the second groove G2. Accordingly, the bending wires BL1 and BL2 arranged on the anti-etching layer ES may be protected from the etching solution.

The anti-etching layer ES may be formed using a slit coater, inkjet, dispenser, or the like. Additionally, the anti-etching layer ES may be formed by a patterning process using a photolithography mask. Here, the anti-etching layer ES may be an etch stop pattern, an etch barrier pattern, or an etch mask pattern.

The first area 110 may include the display area DA and the first non-display area NA1, and may be formed of a transparent glass material.

The first area 110 may include a first top surface 111 in contact with the circuit layer 200, a first bottom surface 112 that is an opposite side of the first top surface 111, and a first side surface 113 connecting the first top surface 111 and the first bottom surface 112. The first area 110 may include a first upper edge where the first top surface 111 and the first side surface 113 meet, and a first lower edge where the first bottom surface 112 and the first side surface 113 meet. Here, the first side surface 113 may be an inclined surface having a predetermined slope with respect to the first bottom surface 112. And, since the first side surface 113 is formed by the etching process, the first lower edge where the first bottom surface 112 and the first side surface 113 meet may have a curved surface.

The second area 120 may be arranged in the non-bending area NBA of the bending area BA, and may be formed of a transparent glass material.

The second area 120 may include a second top surface 121 in contact with the gate insulating layer 220, a second bottom surface 122 that is an opposite side of the second top surface 121, and a second side surface 123 and a third side surface 124 connecting the second top surface 121 and the second bottom surface 122. Here, the second side surface 123 may be a surface arranged to face the first side surface 113.

The second area 120 may include a second upper edge where the second top surface 121 and the second side surface 123 meet, and a second lower edge where the second bottom surface 122 and the second side surface 123 meet. Further, the second area 120 may include a third upper edge where the second top surface 121 and the third side surface 124 meet, and a third lower edge where the second bottom surface 122 and the third side surface 124 meet. Here, the second side surface 123 and the third side surface 124 may be inclined surfaces having a predetermined slope with respect to the second bottom surface 122. And, since the second side surface 123 and the third side surface 124 are formed by the etching process, the second lower edge and he third lower edge may have curved surfaces.

The third area 130 may be arranged in the second non-display area NA2 and may be formed of a transparent glass material.

The third area 130 may include a third top surface 131 that contacts the gate insulating layer 220, a third bottom surface 132 that is an opposite side of the third top surface 131, and a fourth side surface 133 that connects the third top surface 131 and the third bottom surface 132. Here, the fourth side surface 133 may be a surface arranged to face the third side surface 124.

Further, the third area 130 may include a fourth upper edge where the third top surface 131 and the fourth side surface 133 meet, and a fourth lower edge where the third bottom surface 132 and the fourth side surface 133 meet. Here, the fourth side surface 133 may be an inclined surface having a predetermined slope with respect to the third bottom surface 132. And, since the fourth side surface 133 is formed by the etching process, the fourth lower edge may have a curved surface.

The circuit layer 200 may be arranged in the display area DA, and some components of the circuit layer 200 may be arranged in the first non-display area NA1, the bending area BA and the second non-display area NA2. For example, the circuit layer 200 may be arranged on the first top surface 111 of the first area 110, and some components of the circuit layer 200 may be arranged in the first non-display area NA1, the bending area BA and the second non-display area NA2. For example, the gate insulating layer 220, the first interlayer dielectric layer 230 and the second interlayer dielectric layer 260 may be arranged in the first non-display area NA1, the non-bending area NBA of the bending area BA and the second non-display area NA2. Further, the planarization layer 240 may be arranged in the first non-display area NA1, and in a portion of the bending area BA, and in a portion of the second non-display area NA2.

The circuit layer 200 may include the thin film transistor 210, the gate insulating layer 220 covering the gate electrode 211 of the thin film transistor 210, the first interlayer dielectric layer 230 covering the active layer 212, the source electrode 213, and the drain electrode 214 of the thin film transistor 210, the planarization layer 240 arranged on the first interlayer dielectric layer 230, the first electrode 250 arranged on the planarization layer 240, the second interlayer dielectric layer 260 arranged on the first electrode 250, and the second electrode 270 arranged on the second interlayer dielectric layer 260.

The thin film transistor 210 may include the gate electrode 211, the active layer 212, the source electrode 213, and the drain electrode 214.

The gate electrode 211 may be arranged on the first upper surface 111 of the first area 110.

The gate electrode 211 may be made of a conductive material. For example, the gate electrode 211 may be made of a metal material. For example, the gate electrode 211 may be a single layer or a multilayer made of one of molybdenum (Mo), aluminum (Al), chromium (Cr), gold (Au), titanium (Ti), nickel (Ni), neodymium (Nd), and copper (Cu), or an alloy thereof, but is not limited thereto.

The gate insulating layer 220 may be arranged on the first substrate 100, and arranged in the display area DA, the first non-display area NA1, a part of the bending area BA, and the second non-display area NA2 by being etched by the etching process. For example, the gate insulating layer 220 may be arranged on the first area 110 to cover the gate electrode 211.

Since the gate insulating layer 220 may be made of an inorganic insulating material, the gate insulating layer 220 may be etched by the etching process. Therefore, the gate insulating layer 220 may be separated into a gate insulating layer 220 arranged on the first area 110, and a gate insulating layer 220 arranged on the second area 120, and a gate insulating layer 220 arranged on the third area 130.

The gate insulating layer 220 may be made of an inorganic insulating material such as silicon oxide (SiOₓ) and silicon nitride (SiNₓ). The gate insulating layer 220 may be a single layer or a multilayer made of an inorganic insulating material, but is not limited thereto.

The active layer 212 may be arranged on the gate insulating layer 220 arranged on the first area 110. In addition, the active layer 212 may overlap with the gate electrode 211 in the Z-axis direction.

The active layer 212 may be made of amorphous silicon (a-Si), polycrystalline silicon (poly-Si), an oxide semiconductor, an organic semiconductor, etc., but is not necessarily limited thereto.

The source electrode 213 may be arranged on the active layer 212. For example, the source electrode 213 may be located in a different layer from the gate electrode 211. The source electrode 213 may be insulated from the gate electrode 211 by the gate insulating layer 220.

The source electrode 213 may be electrically connected to a source region of the active layer 212, and the source electrode 213 may include an area overlapping with the source region of the active layer 212. For example, the source electrode 213 may directly contact the source region of the active layer 212.

The source electrode 213 may include a conductive material. For example, the source electrode 213 may include a metal such as aluminum (Al), chromium (Cr), copper (Cu), molybdenum (Mo), titanium (Ti), and tungsten (W).

The drain electrode 214 may be arranged on the active layer 212. For example, the drain electrode 214 may be located in a different layer from the gate electrode 211. The drain electrode 214 may be insulated from the gate electrode 211 by the gate insulating layer 220. The drain electrode 214 may be arranged in the same layer as the source electrode 213. The drain electrode 214 may be arranged spaced apart from the source electrode 213.

The drain electrode 214 may be electrically connected to a drain region of the active layer 212, and the drain electrode 214 may include an area overlapping with the drain region of the active layer 212. For example, the drain electrode 214 may directly contact the drain region of the active layer 212.

The drain electrode 214 may include a conductive material. For example, the source electrode 213 may include a metal such as aluminum (Al), chromium (Cr), copper (Cu), molybdenum (Mo), titanium (Ti), and tungsten (W).

The first interlayer dielectric layer 230 arranged on the first substrate 100 may be arranged on the display area DA, the first non-display area NA1, a part of the bending area BA, and the second non-display area NA2 because by being etched first an etching process. For example, the first interlayer dielectric layer 230 may be arranged on the first area 110 to cover the gate electrode 211, etc.

The first interlayer dielectric layer 230 may be arranged on the active layer 212, the source electrode 213, and the drain electrode 214. In such a case, the first interlayer dielectric layer 230 may cover the active layer 212, the source electrode 213, and the drain electrode 214 on the first area 110. Therefore, the first interlayer dielectric layer 230 may protect the active layer 212, the source electrode 213, and the drain electrode 214.

In addition, the first interlayer dielectric layer 230 may be arranged on the first pad PAD1 and the second pad layer PAD2b of the second pad PAD2. In such a case, the first interlayer dielectric layer 230 may be arranged on the second area 120 and the third area 130.

The first interlayer dielectric layer 230 may be made of an inorganic insulating material such as silicon oxide (SiOₓ) and silicon nitride (SiNₓ). The first interlayer dielectric layer 230 may be a single layer or a multilayer made of an inorganic insulating material, but is not limited thereto.

The planarization layer 240 may be arranged on the first interlayer dielectric layer 230. In this case, a planarization layer 240 of the circuit layer 200 may extend to a portion of the bending area BA to be arranged over upper portion the first groove G1. For example, the planarization layer 240 may extend up to the first pad PAD1 arranged in the bending area BA. Accordingly, the planarization layer 240 may overlap with a portion of the second area 120.

The planarization layer 240 may be formed of a transparent organic insulating material. For example, the planarization layer 240 may be formed of one or more materials selected from a polyacrylate resin, an epoxy resin, a phenolic resin, a polyamide resin, a polyimide resin, an unsaturated polyester resin, or an unsaturated polyester resin, polyphenylene ether resin, polyphenylene sulfide resin, and benzocyclobutene, but is not limited thereto. Here, the planarization layer 240 may be a single layer or multiple layers made of organic insulating material.

Since the planarization layer 240 is formed of an organic insulating material that is relatively more ductile than an inorganic insulating material, it may easily respond to bending of the display panel 10. For example, the planarization layer 240 extending from the circuit layer 200 of the display area DA may be arranged in the first bending area BA1, and the planarization layer 240 may be formed of an organic insulating material having good ductility, so that it may be easily bent without damage such as cracking.

A planarization layer 240 extending from the circuit layer 200 in the display area DA may be arranged over the first groove G1. For example, the planarization layer 240 may extend to a portion of the second area 120 through the first non-display area NA1, so that it may cover the upper portion of the first groove G1.

Since the planarization layer 240 may be formed of an organic insulating material having strong corrosion resistance to the etching solution, the etching process is no longer performed by the planarization layer 240. In other words, the planarization layer 240 extending from the circuit layer 200 of the display area DA may serve as an etch stopper, so that it may serve as the first anti-etching layer ES1. Accordingly, the first groove G1 may be formed up to the planarization layer 240 by the etching process, and a portion of the bottom surface of the planarization layer 240 may be exposed through the first groove G1.

In the display device according to the embodiment of the present specification, when the planarization layer 240 serves as an etch stopper, it is not necessary to arrange a separate anti-etching layer ES covering the upper portion of the first groove G1, which may improve process productivity. Furthermore, when the planarization layer 240 serves as an etch stopper over the first groove G1, the first bending wire BL1 arranged over the planarization layer 240 may be protected from the etching solution.

Upon etching of the first substrate 100 to form the first groove G1, the planarization layer 240 may be formed of an organic insulating material having strong corrosion resistance to serve as an etch stopper, but is not necessarily limited thereto. For example, instead of extending the planarization layer 240 of the circuit layer 200 arranged in the display area DA to a portion of the second area 120, a separate first anti-etching layer ES1 may be arranged over the first groove G1.

The first electrode 250 may be arranged on the planarization layer 240. Here, the first electrode 250 may be a common electrode.

The first electrode 250 may be formed of a transparent conductive material or an opaque conductive material. For example, the first electrode 250 may be indium tin oxide (ITO) or indium zinc oxide (IZO) or any other conductive material.

A voltage may be applied to the first electrode 250 and the second electrode 270. Accordingly, the liquid crystal layer 300 may be driven to display an image. Here, a voltage may be applied to the second electrode 270 via the drain electrode 214.

The second interlayer dielectric layer 260 may be arranged in the display area DA, the first non-display area NA1, the bending area BA except for the first bending area BA1 and the second bending area BA2, and the second non-display area NA2.

The second interlayer dielectric layer 260 may be arranged on the first electrode 250. For example, the second interlayer dielectric layer 260 may be arranged over the planarization layer 240 to cover the first electrode 250.

Further, the second interlayer dielectric layer 260 may be arranged on the bending wire BL. For example, the second interlayer dielectric layer 260 may be arranged over the anti-etching layers ES1 and ES2 to cover a portion of the bending wire BL. In this case, in the first non-display area NA1, based on the Z-axis direction, the second interlayer dielectric layer 260 may be arranged between the bending wire BL and a first connection wire LL1. Furthermore, in the non-bending area NBA, based on the z-axis direction, the second interlayer dielectric layer 260 may be arranged between the bending wire BL and the second connection wire LL2 and/or between the bending wire BL and a third connection wire LL3.

Additionally, in the non-bending area NBA and the second non-display area NA2, the second interlayer dielectric layer 260 may be arranged over the first interlayer dielectric layer 230.

The second interlayer dielectric layer 260 may be made of an inorganic insulating material such as silicon oxide (SiOₓ) and silicon nitride (SiNₓ). The second interlayer dielectric layer 260 may be a single layer or a multilayer made of an inorganic insulating material, but is not limited thereto.

The second electrode 270 may be arranged on the second interlayer dielectric layer 260. The second electrode 270 may be electrically connected to the drain electrode through a contact hole formed in the planarization layer 240 and the second interlayer dielectric layer 260. The second electrode 270 may be a pixel electrode.

The second electrode 270 may be made of a transparent conductive material or an opaque conductive material. For example, the second electrode 270 may be made of indium tin oxide (ITO), indium zinc oxide (IZO), or other conductive materials.

The liquid crystal layer 300 may be arranged on the second interlayer dielectric layer 260, the second electrode 270, and the first connection wire LL1, and may include an alignment film (not shown) for easily inducing the arrangement of liquid crystals.

The sealant 310 may surround the liquid crystal layer 300. For example, the sealant 310 may be arranged along the perimeter of the liquid crystal layer 300 to seal the liquid crystal layer 300. Accordingly, the sealant 310 may be a sealing member or a seal line.

Referring to FIG. 3, the sealant 310 may be arranged over the second interlayer dielectric layer 260 and/or on the first connection wire LL1. For example, the sealant 310 may be arranged between the second interlayer dielectric layer 260 and the black matrix 600 based on the Z-axis direction. Alternatively, the sealant 310 may be arranged between the first connection wire LL1 and the black matrix 600 based on the Z-axis direction.

The sealant 310 may be a photocurable or thermocurable epoxy resin. The sealant 310 may form a gap for liquid crystal injection between the second interlayer dielectric layer 260 and the color filter layer 500. The sealant 310 may serve to reduce or prevent leakage of the liquid crystal injected into the gap.

Additionally, the sealant 310 may be a member used to bond the first substrate 100 and the second substrate 700. For example, the sealant 310 may be a member used to bond the second substrate 700 having a color filter layer 500 and a black matrix 600 arranged thereunder to the first substrate 100 having the circuit layer 200 arranged thereon.

Referring to FIG. 3, the at least one column 320 may be arranged on the second interlayer dielectric layer 260. For example, the column 320 may be arranged between the second interlayer dielectric layer 260 and the color filter layer 500 based on the Z-axis direction. Accordingly, the column 320 may maintain the gap for injecting liquid crystal.

The column 320 may include a first column portion 321 and a second column portion 322.

The first column portion 321 may be arranged on the second interlayer dielectric layer 260.

The first column portion 321 may be formed of an organic insulating material, and may be formed together with the pattern layer 400 by the same masking process that forms the pattern layer 400.

The second column portion 322 may be arranged on the first column portion 321, and may overlap with the first column portion 321.

The second column portion 322 may be formed of an organic insulating material.

The pattern layer 400 may be arranged on the bending wire BL. Accordingly, the pattern layer 400 may protect the bending wires BL from physical and/or chemical impact. For example, the pattern layer 400 may reduce or prevent moisture, impurities, or the like, from penetrating into the bending wires BL.

The pattern layer 400 may be arranged in the bending area BA, and as the bending area BA is bent, the pattern layer 400 may also be bent with it. For example, the pattern layer 400 may include a first pattern layer 400a arranged in the first bending area BA1 and a second pattern layer 400b arranged in the second bending area BA2. The first pattern layer 400a may overlap with the first groove G1, and the second pattern layer 400b may overlap with the second groove G2. Accordingly, when the first bending area BA1 and the second bending area BA2 are bent, the first pattern layer 400a and the second pattern layer 400b may be bent.

The pattern layer 400 may be formed of an organic insulating material in order to cope with stress caused by bending. For example, the pattern layer 400 may be formed of an organic material including a polyester-based polymer, an acrylic-based polymer, or the like.

Referring to FIGS. 1 to 4 (A and B), the pattern layer 400 may be provided as a structure having a predetermined width and height H1 and may be arranged along the X-axis direction. For example, the pattern layer 400 may be formed in a bar shape including a trapezoidal cross-section. Here, the height H1 of the pattern layer 400 may be a first height.

The pattern layer 400 may be formed to have a predetermined width. For example, the width of the first pattern layer 400a may be equal to or greater than the width W1 of the first groove G1. Further, the width of the second pattern layer 400b may be equal to or greater than the width W2 of the second groove G2. In this case, the width of the first pattern layer 400a may be smaller than the length of the first bending wire BL1, and the width of the second pattern layer 400b may be smaller than the length of the second bending wire BL2.

The pattern layer 400 may be formed to have the predetermined height H1. And, the height H1 of the pattern layer 400 may be adjustable. Accordingly, in the display panel 10 according to the embodiment of the present specification, the height H1 of the pattern layer 400 may be adjusted to reduce or minimize stresses applied to the bending wire BL.

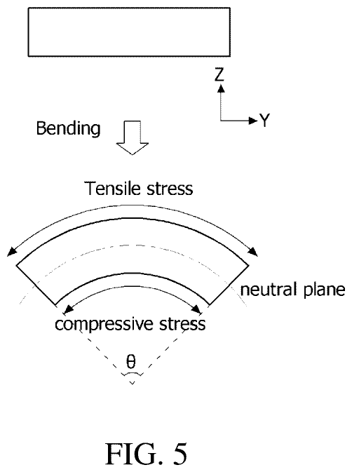

FIG. 5 is a view illustrating a neutral plane according to bending.

Referring to FIG. 5, the neutral plane may be defined as a plane where the stress state is zero during bending, and the magnitude of the tensile or compressive stress is proportional to the distance from the neutral plane. Based on the Z direction, the neutral plane may be located in the center between a surface where the tensile stress acts and a surface where the compressive stress acts. Here, the surface subject to the compressive stress may be defined as a surface arranged close to the center of curvature, and the surface subject to the tensile stress may be defined as a surface opposite the surface subject to the compressive stress.

Components arranged in an area subjected to the compressive stress are more prone to cracking than components arranged in an area subjected to tensile stress. For example, since the first bending wire BL1 arranged in the first bending area BA1 of the display panel 10 and the second bending wire BL2 arranged in the second bending area BA2 may be arranged in the area subject to tensile stress, there is a relatively high possibility that cracks will occur in the first bending wire BL1 and/or the second bending wire BL2 due to bending of the display panel 10. Since the area subject to the tensile stress is more susceptible to cracking than the area subject to the compressive stress during bending, the neutral surface may be moved closer to the first bending wire BL1 and/or the second bending wire BL2, thereby minimizing the stresses applied to the first bending wire BL1 and/or the second bending wire BL2.

Accordingly, when the pattern layer 400 is arranged on the bending wire BL (see FIG. 3), the display device according to one embodiment of the present specification may position the neutral plane on the bending wire BL or move the neutral plane to be closer to the bending wire BL by adjusting the height H1 of the pattern layer 400 in a state where the thickness from the pattern layer 400 to the bending wire BL is determined. Therefore, the display panel 10 may reduce stress applied to the bending wire BL during the bending of the display panel 10 by using the pattern layer 400.

The color filter layer 500 may be arranged on the liquid crystal layer 300. In such a case, the color filter layer 500 may be arranged in the display area DA. In addition, the color filter layer 500 may be formed on the same layer as the black matrix 600.

The color filter layer 500 may include red, green, and blue color filters. For example, the color filter layer 500 may include an acrylic resin and a pigment. The color filter layer 500 may be classified into red, green, and blue depending on the type of pigment that implements a color.

The black matrix 600 may be arranged in the first non-display area NA1, and may be arranged on the liquid crystal layer 300 and the sealant 310.

In addition, the black matrix 600 may have a closed loop shape surrounding the display area DA. Therefore, the black matrix 600 may reduce or prevent light leakage. In such a case, the black matrix 600 may overlap with the color filter layer 500 in the X-axis direction and the Y-axis direction.

The second substrate 700 may be arranged on the color filter layer 500 and the black matrix 600. Therefore, the second substrate 700 may protect the color filter layer 500 and the black matrix 600.

An end of the second substrate 700 may protrude further than the black matrix 600 in the Y-axis direction, but is not necessarily limited thereto. For example, the end of the second substrate 700 may also be arranged to overlap with an end of the black matrix 600 in the Z-axis direction.

The second substrate 700 may be made of a transparent plastic material, a glass material, or a reinforced glass material.

The upper polarization layer UPOL may be arranged on the second substrate 700. The upper polarization layer UPOL may overlap with the color filter layer 500, and may be arranged in the display area DA.

The lower polarization layer DPOL may be arranged below the first area 110. For example, the lower polarization layer DPOL may be attached to the lower side of the first area 110 through an adhesive member.

The protective layer 800 may be arranged over the pattern layer 400. For example, the protective layer 800 may be arranged to cover the pattern layer 400. In this case, the protective layer 800 may cover a portion of the connection wire LL arranged above the anti-etching layer ES.

Accordingly, the protective layer 800 may protect a portion of the bending wire BL and/or the connection wire LL from physical and/or chemical impacts together with the pattern layer 400. Here, the protective layer 800 may be an upper micro-coating layer, or an upper coating layer.

The protective layer 800 may be formed of an organic insulating material in order to cope with stress caused by bending. For example, the protective layer 800 may be formed of an organic material including an acrylic-based material such as an acrylate polymer, or the like, but is not necessarily limited thereto.

The protective layer 800 may be formed as a structure having a predetermined width and height H2. Therefore, like the pattern layer 400, the position of the neutral plane may be adjusted by adjusting the height H2 of the protective layer 800. Here, the height H2 of the protective layer 800 may be a second height.

The protective layer 800 may include a first protective layer 800a and a second protective layer 800b spaced apart from each other in the Y-axis direction.

The first protective layer 800a may be arranged on the first pattern layer 400a and may overlap with the first groove G1. As the first bending area BA1 is bent, the first protective layer 800a may also be bent with it. In this case, the first protective layer 800a may cover a portion of the connection wire LL above the first anti-etching layer ES1.

A portion of the first protective layer 800a may be arranged in the inside of a groove G1ES1 concavely formed in the top surface of the first anti-etching layer ES1. Here, the groove G1ES1 of the first anti-etching layer ES1 may be a first upper groove, or a planarization groove.

Accordingly, a portion of the first protective layer 800a may overlap with the first anti-etching layer ES1 in a horizontal direction. In this case, a portion of a second connection wire LL2 may also be arranged in the inside of the groove G1ES1 formed in the first anti-etching layer ES1, but is not necessarily limited thereto. For example, the grooves G1ES1 formed in the first anti-etching layer ES1 may be spaced apart from each other along the X-axis direction, so that the second connection wire LL2 may be arranged between the grooves G1ES1. Here, a portion of the protective layer 800 arranged in the inside of the grooves G1ES1 may be a protrusion 810 or a first protrusion of the first protective layer 800a.

The first protective layer 800a may implement a reinforced structure with a portion of it arranged in the inside of the groove G1ES1 formed in the first anti-etching layer ES1. For example, a portion of the first protective layer 800a may be arranged in the groove G1ES1 of the first anti-etching layer ES1 that is arranged adjacent to the first bending area BA1, so that even if stress caused by bending is applied to the first protective layer 800a, the portion of the first protective layer 800a arranged in the groove G1ES1 may be supported by the first anti-etching layer ES1. Accordingly, the first protective layer 800a may cope with stress caused by bending through the portion of the first protective layer 800a arranged in the groove G1ES1. For example, the engagement of the protrusion 810 of the first protective layer 800a and the groove G1ES1 allows the first protective layer 800a to resist deformation upon bending.

The second protective layer 800b may be arranged on the second pattern layer 400b and may overlap with the second groove G2. As the second bending area BA2 is bent, the second protective layer 800b may also be bent with it. In this case, the second protective layer 800b may cover a portion of the connection wire LL above the second anti-etching layer ES2.

Some portions of the second protective layer 800b may be arranged in the inside of grooves G2ES2 and G3ES2 concavely formed in the top surface of the second anti-etching layer ES2. For example, the second anti-etching layer ES2 may include two second upper groove G2ES2 and a third upper groove G3ES2 spaced apart from each other with the second bending wire BL2 interposed therebetween.

Accordingly, a portion of the second protective layer 800b may overlap with the second anti-etching layer ES2 in a horizontal direction. In this case, a portion of the third connection wire LL3 and a portion of a fourth connection wire LL4 may also be arranged in the inside of the grooves G2ES2 and G3ES2 formed in the second anti-etching layer ES2, but is not necessarily limited thereto. For example, the grooves G2ES2 formed in the second anti-etching layer ES2 may be spaced apart from each other along the X-axis direction, so that the third connection wire LL3 may be arranged between the grooves G2ES2. Further, the grooves G3ES2 formed in the second anti-etching layer ES2 may be spaced apart from each other along the X-axis direction, so that the fourth connection wire LL4 may be arranged between the grooves G3ES2. Here, the portion of the protective layer 800 arranged in the inside of the second upper groove G2ES2 may be a protrusion 820 of the second protective layer 800b, an inner protrusion of the second protective layer 800b, or a second protrusion. Additionally, the portion of the protective layer 800 arranged in the inside of the third upper groove G3ES2 may be a protrusion 830 of the second protective layer 800b, an outer protrusion of the second protective layer 800b, or a third protrusion.

The second protective layer 800b may implement a reinforced structure with some portions of it arranged in the inside of the groove G2ES2 and G3ES2 formed in the second anti-etching layer ES2. For example, some portions of the second protective layer 800b may be arranged in the grooves G2ES2 and G3ES2 of the second anti-etching layer ES2 that are arranged adjacent to the second bending area BA2, so that even if stress caused by bending is applied to the second protective layer 800b, the portions of the second protective layer 800b arranged in the grooves G2ES2 and G3ES2 may be supported by the second anti-etching layer ES2. Accordingly, the second protective layer 800b may cope with stress caused by bending, through use of the portions of the second protective layer 800b arranged in the grooves G2ES2 and G3ES2. For example, the engagement of the protrusion 820 of the second protective layer 800b with the second upper groove G2ES2 and the engagement of the protrusion 830 of the second protective layer 800b with the third upper groove G3ES2 may allow the second protective layer 800b to resist deformation upon bending.

With the portions of the second protective layer 800b arranged in the inside of the grooves G2ES2 and G3ES2, the second protective layer 800b may improve its resistance to deformation caused by bending.

The display panel 10 may include two bending wires BL arranged to correspond to each of the first groove G1 and the second groove G2, and one of the two bending wires BL may overlap with the first groove G1 and the other may overlap with the second groove G2. Accordingly, the first bending wire BL1 may be arranged on the first anti-etching layer ES1, and the second bending wire BL2 may be arranged on the second anti-etching layer ES2. If the first anti-etching layer ES1 is a planarization layer 240 extending from the circuit layer 200, the first bending wire BL1 may be arranged on the planarization layer 240.

The bending wire BL may be arranged in the first non-display area NA1, the bending area BA, and the second non-display area NA2.

Based on the Y-axis direction, the first bending wire BL1 may be formed longer than the first bending area BA1. For example, the length of the first bending wire BL1 in the Y-axis direction may be greater than the width W1 of the first groove G1. Accordingly, the first bending wire BL1 may be arranged in a portion of the first non-display area NA1 and a portion of the bending area BA.

Further, based on the Y-axis direction, the second bending wire BL2 may be formed longer than the second bending area BA2. For example, the length of the second bending wire BL2 in the Y-axis direction may be greater than the width W2 of the second groove G2. Accordingly, the second bending wire BL2 may be arranged in a portion of the bending area BA and a portion of the second non-display area NA2.

The bending wire BL may be formed of a conductive material. For example, the bending wire BL may be formed of a metallic material. For example, the bending wire BL may be a single layer or multiple layers made of any one of indium tin oxide (ITO), indium zinc oxide (IZO), molybdenum (Mo), aluminum (Al), chromium (Cr), gold (Au), titanium (Ti), nickel (Ni), neodymium (Nd), and copper (Cu), or an alloy thereof, but is not limited thereto. For example, the bending wire BL may be formed as a double-layer structure.

The bending wire BL may include a first layer BLL1 and a second layer BLL2. The first layer BLL1 and the second layer BLL2 may be made of different materials. Accordingly, the bending wire BL may easily respond to stress caused by bending.

At least one of the first layer BLL1 and the second layer BLL2 of the bending wire BL may include the same metal layer as the first electrode 250.

Further, the first layer BLL1 and the second layer BLL2 of the bending wire BL may be made of a material different from that of the first electrode 250.

The first layer BLL1 may be arranged on the anti-etching layers ES1 and ES2. And, the first layer BLL1 may be formed of transparent indium tin oxide (ITO) or indium zinc oxide (IZO). For example, the first layer BLL1 may include the same material as the first electrode 250, and may be formed together with the first electrode 250 through the same mask process that forms the first electrode 250.

The second layer BLL2 may be arranged over the first layer BLL1. Based on the Y-axis direction, the second layer BLL2 may have the same length as the first layer BLL1, but is not necessarily limited thereto.

The second layer BLL2 may be formed of a material different from that of the first layer BLL1. For example, the second layer BLL2 may be made of any one of molybdenum (Mo), aluminum (Al), chromium (Cr), gold (Au), titanium (Ti), nickel (Ni), neodymium (Nd), and copper (Cu), or an alloy thereof. For example, the second layer BLL2 may include copper (Cu).

Further, the bending wire BL may include a material different from that of the connection wire LL. For example, the connection wire LL may be formed of indium tin oxide (ITO) or indium zinc oxide (IZO), and the second layer BLL2 of the bending wire BL may be formed of copper, so that the bending wire BL may include a material different from that of the connection wire LL.

As such, since via two bending wires BL, the first connection wire LL1 and the second connection wire LL2 are connected and the third connection wire LL3 and the fourth connection wire LL4 are connected, the display device according to the embodiment of the present specification may easily respond to stress due to bending. Furthermore, since the bending wire BL includes at least two layers including different materials, it may be possible to respond more effectively to the stress due to bending. Here, the first connection wire LL1 may be a first link line, the second connection wire LL2 may be a second link line, the third connection wire LL3 may be a third link line, and the fourth connection wire LL4 may be a fourth link line.

The connection wire LL may include a first connection wire LL1 arranged in the first non-display area NA1, a second connection wire LL2 and a third connection wire LL3 arranged in the non-bending area NBA with the first pad PAD1 interposed therebetween, and a fourth connection wire LL4 arranged in the second non-display area NA2.

The first connection wire LL1 and the second connection wire LL2 may be connected via the first bending wire BL1. For example, a first pattern layer 400a may be arranged between the first connection wire LL1 and the second connection wire LL2 based on the Y-axis direction. In this case, the first bending wire BL1 arranged under the first pattern layer 400a may be electrically connected with the first connection wire LL1 through the first contact hole CH1 and may be electrically connected with the second connection wire LL2 through the second contact hole CH2. Accordingly, the first connection wire LL1 may be in contact with one side of the first bending wire BL1 and the second connection wire LL2 may be in contact with the other side of the first bending wire BL1. Here, the first contact hole CH1 and the second contact hole CH2 may be formed to penetrate the second interlayer dielectric layer 260.

The first connection wire LL1 may be arranged in the first non-display area NA1. For example, the first connection wire LL1 may be arranged on the second interlayer dielectric layer 260 of the first non-display area NA1. And, the first connection wire LL1 may be electrically connected with the first bending wire BL1 through a first contact hole CH1 penetrating the second interlayer dielectric layer 260 in the first non-display area NA1.

The second connection wire LL2 may be arranged in the non-bending area NBA.

The second connection wire LL2 may include a first part LL2a and a second part LL2b.

The first part LL2a of the second connection wire LL2 may be arranged on the second interlayer dielectric layer 260 of the non-bending area NBA and may be electrically connected with the first bending wire BL1 through the second contact hole CH2.

The second part LL2b of the second connection wire LL2 may be arranged on the gate insulating layer 220. Further, the first part LL2a and the second part LL2b may be electrically connected through a third contact hole CH3. Here, the third contact hole CH3 may be a contact hole penetrating the first interlayer dielectric layer 230, the first anti-etching layer ES1, and the second interlayer dielectric layer 260. In this case, the second part LL2b may be electrically connected with the first intermediate pad layer PAD1M of the first pad PAD1. More specifically, the second part LL2b may be electrically connected with the inner intermediate pad layer PAD1Ma of the first pad PAD1, but is not necessarily limited thereto. For example, the second part LL2b may be electrically connected with an inner lower pad layer PAD1Da of the first lower pad layer PAD1D of the first pad PAD1. Here, the second part LL2b and the inner intermediate pad layer PAD1Ma may be integrally formed by the same masking process. Here, the term “inner” may refer to the direction toward the display area DA, and the term “outer” may refer to the direction opposite to the inner.

The third connection wire LL3 and the fourth connection wire LL4 may be connected via the second bending wire BL2. For example, a second pattern layer 400b may be arranged between the third connection wire LL3 and the fourth connection wire LL4 based on the Y-axis direction. In this case, the second bending wire BL2 arranged under the second pattern layer 400b may be electrically connected with the third connection wire LL3 through the fifth contact hole CH5 and electrically connected with the fourth connection wire LL4 through the sixth contact hole CH6. Accordingly, the third connection wire LL3 may be in contact with one side of the second bending wire BL2 and the fourth connection wire LL4 may be in contact with the other side of the second bending wire BL2. Here, the fifth contact hole CH5 and the sixth contact hole CH6 may be formed to penetrate the second interlayer dielectric layer 260.

The third connection wire LL3 may be arranged in the non-bending area NBA.

The third connection wire LL3 may include a third part LL3a and a fourth part LL3b.

The third part LL3a of the third connection wire LL3 may be arranged on the second interlayer dielectric layer 260 of the non-bending area NBA and may be electrically connected with the second bending wire BL2 through the fifth contact hole CH5.

The fourth part LL3b of the third connection wire LL3 may be arranged on the gate insulating layer 220. Further, the third part LL3a and the fourth part LL3b may be electrically connected through a fourth contact hole CH4. Here, the fourth contact hole CH4 may be a contact hole penetrating the first interlayer dielectric layer 230, the second anti-etching layer ES2, and the second interlayer dielectric layer 260. In this case, the fourth part LL3b may be electrically connected with the first intermediate pad layer PAD1M of the first pad PAD1. More specifically, the fourth part LL3b may be electrically connected with the outer intermediate pad layer PAD1Mb of the first pad PAD1, but is not necessarily limited thereto. For example, the fourth part LL3b may be electrically connected with an outer lower pad layer PAD1Db of the first lower pad layer PAD1D of the first pad PAD1. Here, the fourth part LL3b and the outer intermediate pad layer PAD1Mb may be integrally formed by the same masking process.

The fourth connection wire LL4 may be arranged in the second non-display area NA2.

The fourth connection wire LL4 may include a fifth part LL4a and a sixth part LL4b.

The fifth part LL4a of the fourth connection wire LL4 may be arranged on the second interlayer dielectric layer 260 of the second non-display area NA2 and may be electrically connected with the second bending wire BL2 through the sixth contact hole CH6.

The sixth part LL4b of the fourth connection wire LL4 may be arranged on the gate insulating layer 220. Further, the fifth part LL4a and the sixth part LL4b may be electrically connected through a seventh contact hole CH7. Here, the seventh contact hole CH7 may be a contact hole penetrating the first interlayer dielectric layer 230, the second anti-etching layer ES2, and the second interlayer dielectric layer 260. In this case, the sixth part LL4b may be electrically connected with the second intermediate pad layer PAD2M of the second pad PAD2, but is not necessarily limited thereto. For example, the sixth part LL4b may be electrically connected with the second lower pad layer PAD2D of the second pad PAD2. Here, the fourth part LL3b and the second intermediate pad layer PAD2M may be integrally formed by the same mask process.

The first pad PAD1 may be arranged in the non-bending area NBA. And, the first pad PAD1 may be formed to be exposed to the outside for connection with the chip 20.

Referring to FIGS. 3 and 4, the first pad PAD1 may include a first lower pad layer PAD1D arranged on the second area 120, a first intermediate pad layer PAD1M arranged on the gate insulating layer 220 to overlap with the first lower pad layer PAD1D, and a first upper pad layer PAD1U arranged on the second interlayer dielectric layer 260 to overlap with the first intermediate pad layer PAD1M.

At least one of the first lower pad layer PAD1D, the first intermediate pad layer PAD1M, and the first upper pad layer PAD1U may be made of a material different from that of the other one. For example, the first upper pad layer PAD1U may be made of a material different from that of the first lower pad layer PAD1D and/or the first intermediate pad layer PAD1M. For example, the first lower pad layer PAD1D, the first intermediate pad layer PAD1M, and the first upper pad layer PAD1U may be formed of different materials. Further, the first lower pad layer PAD1D, the first intermediate pad layer PAD1M, and the first upper pad layer PAD1U may be formed using different manufacturing processes.

The first lower pad layer PAD1D may be formed together with the gate electrode 211 by the same mask process that forms the gate electrode 211. Further, the first intermediate pad layer PAD1M may be formed together with the source electrode 213 and the drain electrode 214 by the same mask process that forms the source electrode 213 and the drain electrode 214. Further, the first upper pad layer PAD1U may be formed together with the connection wire LL by the same mask process that forms the connection wire LL.

The first upper pad layer PAD1U, the first intermediate pad layer PAD1M, and the first lower pad layer PAD1D may be electrically connected. For example, the first upper pad layer PAD1U may be electrically connected with the first intermediate pad layer PAD1M through contact hole penetrating the first interlayer dielectric layer 230 and the second interlayer dielectric layer 260. Further, the first intermediate pad layer PAD1M may be electrically connected to the first lower pad layer PAD1D through contact hole penetrating the gate insulating layer 220.

An upper portion of the first upper pad layer PAD1U may be exposed to the outside for connection with the chip 20. Accordingly, the chip 20 may be arranged on the upper portion of the exposed first upper pad layer PAD1U. In this case, the first upper pad layer PAD1U may be arranged between the first anti-etching layer ES1 and the second anti-etching layer ES2, and may be overlapped with the first anti-etching layer ES1 and the second anti-etching layer ES2 in the Y-axis direction. And, since, based on the top surface of the substrate 100, the arrangement position of the first upper pad layer PAD1U is lower than the heights of the first anti-etching layer ES1 and the second anti-etching layer ES2, a groove may be formed between the first anti-etching layer ES1 and the second anti-etching layer ES2. And, since the chip 20 is arranged in the groove, a narrow bezel of the display device may be easily implemented when the display panel 10 is bent.

The first upper pad layer PAD1U may include an inner upper pad layer PAD1Ua and an outer upper pad layer PAD1Ub arranged corresponding to an input end (or input terminal) and an output end (or output terminal) of the chip 20, respectively. And, the inner upper pad layer PAD1Ua and the outer upper pad layer PAD1Ub may be spaced apart from each other. In this case, the inner upper pad layer PAD1Ua and the outer upper pad layer PAD1Ub may be electrically connected with the chip 20.

Further, the first intermediate pad layer PAD1M may include an inner intermediate pad layer PAD1Ma connected with the inner upper pad layer PAD1Ua, and an outer intermediate pad layer PAD1Mb connected with the outer upper pad layer PAD1Ub. And, the inner intermediate pad layer PAD1Ma and the outer intermediate pad layer PAD1Mb may be spaced apart from each other. Here, the inner intermediate pad layer PAD1Ma may be connected with the second part LL2b of the second connection wire LL2. And, the outer intermediate pad layer PAD1Mb may be connected with the fourth part LL3b of the third connection wire LL3.

Further, the first intermediate pad layer PAD1M may include an inner lower pad layer PAD1Da connected with the inner intermediate pad layer PAD1Ma, and an outer lower pad layer PAD1Db connected with the outer intermediate pad layer PAD1Mb. The inner lower pad layer PAD1Da and the outer lower pad layer PAD1Db may be spaced apart from each other.

The second pad PAD2 may be arranged in the second non-display area NA2.

Referring to FIGS. 3 and 5, the second pad PAD2 may include a second lower pad layer PAD2D arranged on the third area 130, a second intermediate pad layer PAD2M arranged on the gate insulating layer 220 to overlap with the second lower pad layer PAD2D, and a second upper pad layer PAD2U arranged on the second interlayer dielectric layer 260 to overlap with the second intermediate pad layer PAD2M. Here, the second upper pad layer PAD2U may be electrically connected with the circuit board 30. Further, the second intermediate pad layer PAD2M may be connected with the sixth part LL4b of the fourth connection wire LL4.

At least one of the second lower pad layer PAD2D, the second intermediate pad layer PAD2M, and the second upper pad layer PAD2U may be made of a material different from that of the other one. For example, the second upper pad layer PAD2U may be made of a material different from that of the second lower pad layer PAD2D and/or the second intermediate pad layer PAD2M. For example, the second lower pad layer PAD2D, the second intermediate pad layer PAD2M, and the second upper pad layer PAD2U may be formed of different materials. Further, the second lower pad layer PAD2D, the second intermediate pad layer PAD2M, and the second upper pad layer PAD2U may be formed using different manufacturing processes.

The second lower pad layer PAD2D may be formed together with the gate electrode 211 by the same mask process that forms the gate electrode 211. Further, the second intermediate pad layer PAD2M may be formed together with the source electrode 213 and the drain electrode 214 by the same mask process that forms the source electrode 213 and the drain electrode 214. Further, the second upper pad layer PAD2U may be formed together with the connection wire LL by the same mask process that forms the connection wire LL.

The second upper pad layer PAD2U, the second intermediate pad layer PAD2M, and the second lower pad layer PAD2D may be electrically connected. For example, the second upper pad layer PAD2U may be electrically connected with the second intermediate pad layer PAD2M through contact hole penetrating the first interlayer dielectric layer 230 and the second interlayer dielectric layer 260. Further, the second intermediate pad layer PAD2M may be electrically connected with the second lower pad layer PAD2D through contact hole penetrating the gate insulating layer 220.

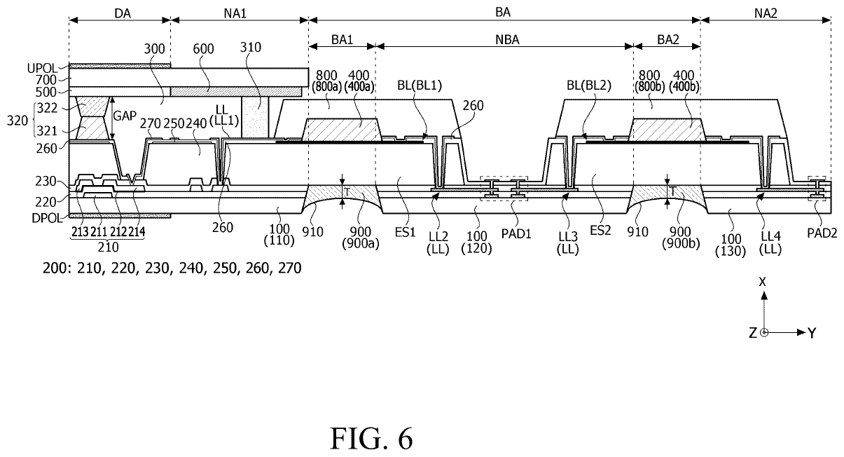

FIG. 6 is a view illustrating a coating layer arranged in the display panel according to the embodiment of the present specification.

Referring to FIG. 6, the display panel 10 according to the embodiment of the present specification may further include a coating layer 900 arranged in the grooves G1 and G2.

The coating layer 900 may be arranged under of the anti-etching layer ES to overlap with a portion of the bending wire BL. Here, the bottom surface 910 of the coating layer 900 may be concavely formed toward the anti-etching layer ES, but is not necessarily limited thereto. For example, the bottom surface 910 of the coating layer 900 may be substantially flat.

The coating layer 900 may be formed of an organic material including a polyester-based polymer or an acrylic-based polymer.

The coating layer 900 may be formed to have a predetermined thickness T in consideration of the position of the neutral plane.

The display device according to an embodiment of the present specification may adjust the thickness T of the coating layer 900 with the thickness from the anti-etching layer ES to the bending wire BL or from the anti-etching layer ES to the pattern layer 400 or from the anti-etching layer ES to the protective layer 800 determined. Therefore, the position of the neutral plane may be on the bending wire BL or moved close to the bending wire BL. Accordingly, the display panel 10 may reduce stress applied to the bending wire BL during the bending of the display panel 10 by using the coating layer 900.

The coating layer 900 may include a first coating layer 900a arranged in the first groove G1 and a second coating layer 900b arranged in the second groove G2.

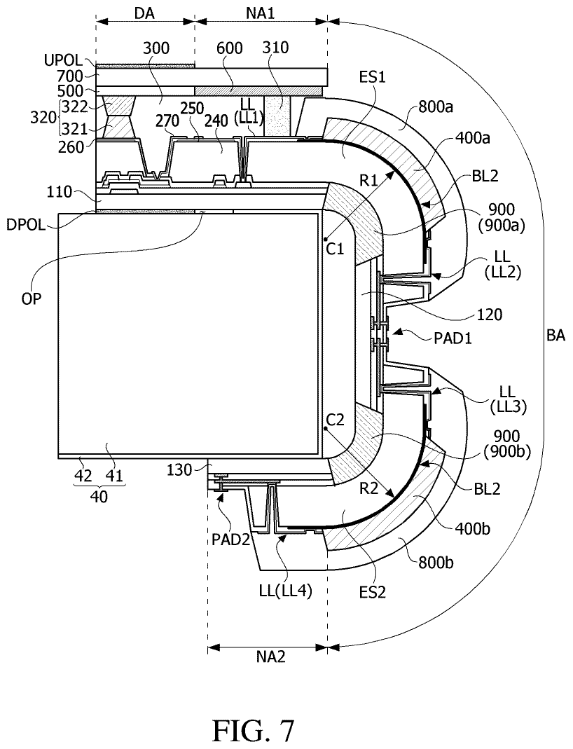

FIG. 7 is a view illustrating a bent appearance of the display device according to the embodiment of the present specification.

Referring to FIG. 7, the display panel 10 of the display device according to the embodiment of the present specification may be bent. For example, as the bending area BA is bent, the display panel 10 may be bent so that the first area 110 and the third area 130 face each other. More specifically, as the first bending area BA1 and the second bending area BA2 are bent, the display panel 10 may be bent such that the first area 110 and the third area 130 face each other.

The center of curvature of the first bending area BA1 may be different from that of the second bending area BA2. For example, the first center of curvature C1 of the first bending wire BL1 may be different from the second center of curvature C2 of the second bending wire BL2. In this case, the first bending wire BL1 may be bent to have a first curvature radius R1. And, the second bending wire BL2 may be bent to have a second radius of curvature R2. Here, the first radius of curvature R1 and the second radius of curvature R2 may be the same, but are not necessarily limited thereto.

Since the gate insulating layer 220, the first interlayer dielectric layer 230, and the second interlayer dielectric layer 260 made of an inorganic insulating material are not arranged in the first bending area BA1 and the second bending area BA2 of the display panel 10 according to the embodiment of the present specification, damage to the gate insulating layer 220, the first interlayer dielectric layer 230, and the second interlayer dielectric layer 260 due to bending may be reduced or prevented in advance.

As the first bending area BA1 and the second bending area BA2 are bent, a light source 40 may be arranged between the first area 110 and the third area 130. Here, the light source 40 may emit light toward the first area 110. Accordingly, the light source 40 may overlap with the first area 110 in the Z-axis direction.

The light source 40 may include a backlight unit 41 and a case 42 surrounding the backlight unit 41.

The backlight unit 41 may emit light toward the first area 110. The light source used in the backlight unit 41 may use a light emitting diode (LED), but is not necessarily limited thereto.

The case 42 may be arranged to surround the backlight unit 41 to protect the backlight unit 41. Further, the case 42 may include an opening OP formed to allow light from the backlight unit 41 to be emitted.

The opening OP may be arranged towards the first area 110. In addition, the lower polarization layer DPOL may be arranged in the opening OP.

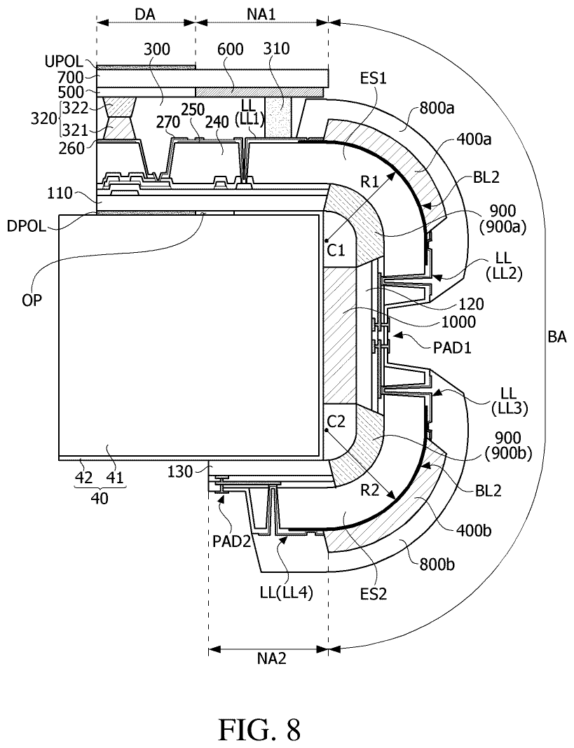

FIG. 8 is a view illustrating a thermal conductive member of the display device according to the embodiment of the present specification.

Referring now to FIG. 8, a display device according to the embodiment of the present specification may include a thermal conductive member 1000.

The thermal conductive member 1000 may be arranged between the second area 120 and the case 42. Accordingly, heat generated by the chip 20 may be transferred through the second area 120 and the thermal conductive member 1000 to the case 42 and then dissipated. For example, because the case 42 has a larger heat dissipation area than the second area 120, the heat generated by the chip 20 may be effectively dissipated after being transferred to the case 42 via the thermal conductive member 1000. In this case, the case 42 may be formed of a metal material. Here, the thermal conductive member 1000 may be formed of at least one of a heat transfer pad, a thermal conductive resin layer, and a thermal grease with high thermal conductivity.

Furthermore, since the second area 120 is attached to the case 42 via the thermal conductive member 1000, a reinforced structure against external forces may be implemented. For example, when a predetermined load is applied to the second area 120, the second area 120 may be supported by the case 42. Accordingly, the rigidity in the non-bending area NBA against external forces may be improved.

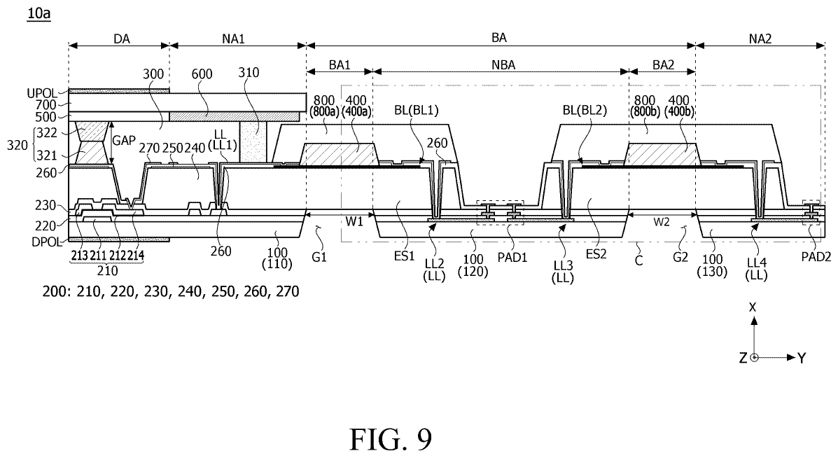

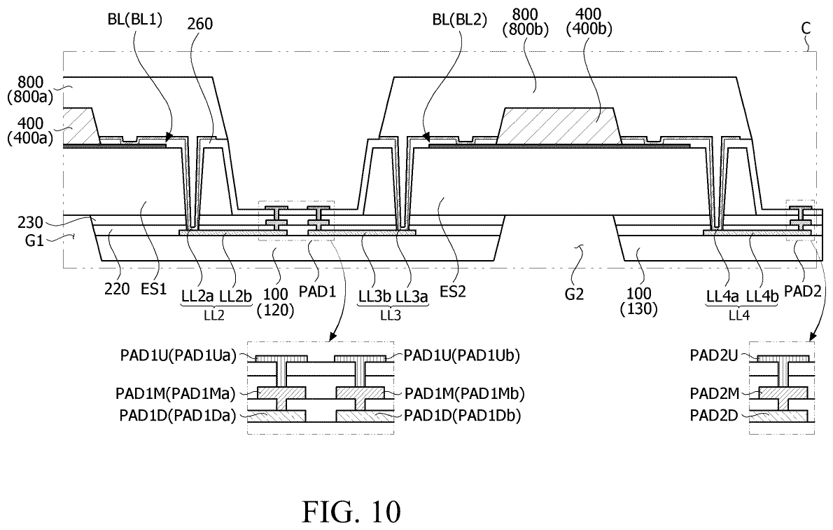

FIG. 9 is a view illustrating one embodiment of connection wire arranged in the display panel according to the embodiment of the present specification. FIG. 10 is an enlarged view of area C in FIG. 9. For example, FIGS. 9 and 10 may be diagrams illustrating a second embodiment of a connection relationship of the first pad PAD1, the second pad PAD2, and the connection wire LL arranged on the display panel. And, the display panel 10 shown in FIGS. 3 and 4 may be a display panel 10 illustrating a first embodiment of a connection relationship of the first pad PAD1, the second pad PAD2, and the connection wire LL. Here, FIG. 9 may be a diagram illustrating a connection wire arranged on lines I-I′.

Referring to FIGS. 3, 4 (A and B), 9, and 10, comparing the display panel 10 according to the first embodiment with the display panel 10a according to the second embodiment, the display panel 10a according to the second embodiment may include a second part LL2b of the second connection wire LL2, a fourth part LL3b of the third connection wire LL3, and a sixth part LL4b of the fourth connection wire LL4 located on the substrate 100. In this case, the display panel 10a according to the second embodiment may be applied to the display device according to the embodiment of the present specification instead of the display panel 10 according to the first embodiment.

In describing the display panel 10a according to the second embodiment with reference to FIGS. 3, 4 (A and B), 9, and 10, the substantially identical components of the display panel 10 according to the first embodiment and the display panel 10a according to the second embodiment may be indicated by the same reference numerals, so that a detailed description thereof may be omitted or simplified.

Referring now to FIGS. 9 and 10, a display panel 10a includes the substrate 100 including the first area 110, the second area 120 and the third area 130 spaced apart from each other by the first groove G1 and the second groove G2, the circuit layer 200 arranged on the substrate 100, the liquid crystal layer 300 arranged on the circuit layer 200, the first pad PAD1 arranged on the second area 120, the second pad PAD2 arranged on the third area 130, and the plurality of connection wires LL and the plurality of bending wires BL. The display panel 10a may also include the first anti-etching layer ES1, the second anti-etching layer ES2, the sealant 310, the column 320, the pattern layer 400, the color filter layer 500, the black matrix 600, the second substrate 700, the lower polarization layer DPOL and the upper polarization layer UPOL, the protective layer 800, and the coating layer 900.

The second connection wire LL2 arranged in the display panel 10a may include the first part LL2a and the second part LL2b. The second part LL2b may be electrically connected with the inner lower pad layer PAD1Da of the first lower pad layer PAD1D of the first pad PAD1.

The first part LL2a and the second part LL2b may be electrically connected through the third contact hole CH3. Here, the third contact hole CH3 may be a contact hole penetrating the gate insulating layer 220, the first interlayer dielectric layer 230, the first anti-etching layer ES1, and the second interlayer dielectric layer 260.

The third connection wire LL3 arranged in the display panel 10a may include the third part LL3a and the fourth part LL3b. The fourth part LL3b may be electrically connected with the outer lower pad layer PAD1Db of the first lower pad layer PAD1D of the first pad PAD1.

The third part LL3a and the fourth part LL3b may be electrically connected through the fourth contact hole CH4. Here, the fourth contact hole CH4 may be a contact hole penetrating the gate insulating layer 220, the first interlayer dielectric layer 230, the second anti-etching layer ES2, and the second interlayer dielectric layer 260.

The fourth connection wire LL4 arranged in the display panel 10a may include the fifth part LL4a and the sixth part LL4b. The sixth part LL4b may be electrically connected with the second lower pad layer PAD2D of the second pad PAD2.

The fifth part LL4a and the sixth part LL4b may be electrically connected through the seventh contact hole CH7. Here, the seventh contact hole CH7 may be a contact hole penetrating the gate insulating layer 220, the first interlayer dielectric layer 230, the second anti-etching layer ES2, and the second interlayer dielectric layer 260.

Referring to FIG. 2, the plurality of second connection wires LL2 and third connection wires LL3 may be connected to one first pad PAD1. In this case, among the plurality of second connection wires LL2 in the X-axis direction, the length of the second connection wire LL2 connected to the center side of the first pad PAD1 and the length of the second connection wire LL2 connected to the edge side of the first pad PAD1 may be different when viewed in the Z-axis direction.

For example, the length of the second connection wire LL2 connected adjacent to the edge side in the X-axis direction of the first pad PAD1 may be longer on a plane than the length of the second connection wire LL2 connected to the center side of the first pad PAD1. As a result, when the connection wire LL is arranged like the connection wire LL in the display panel 10 according to the first embodiment, the resistance of the second connection wire LL2 connected to the edge side of the first pad PAD1 may be relatively larger than the resistance of the second connection wire LL2 connected to the center side of the first pad PAD1. This difference in resistance in the second connection wire LL2 may affect signal transmission through the second connection wire LL2. For example, the difference in resistance between the second connection wire LL2 connected to the center side of the first pad PAD1 and the second connection wire LL2 connected to the edge side of the first pad PAD1 may affect signal transmission from the circuit board 30 to the circuit layer 200.

A plurality of fourth connection wires LL4 may be connected to one second pad PAD2. In this case, the width in the X-axis direction of the second pad PAD2 may be different from the width in the X-axis direction of the first pad PAD1. As a result, among the plurality of fourth connection wires LL4 based on the X-axis direction, the length of the fourth connection wire LL4 connected to the center side of the second pad PAD2 and the length of the fourth connection wire LL4 connected to the edge side of the second pad PAD2 may be different on the plane. In other words, the fourth connection wire LL4 may also have a resistance difference depending on the arrangement position on the plane just like the second connection wire LL2.

Therefore, in the display device according to the embodiment of the present specification, by selecting the arrangement position and material of the second part LL2b, the arrangement position and material of the fourth part LL3b and the arrangement position and material of the sixth part LL4b, the resistance may be adjusted according to the position of each of the connection wires LL. Accordingly, the resistance difference of the connection wires LL depending on the position may be reduced or minimized. For example, the connection wire LL connected to the center side of the first pad PAD1 may be arranged like the connection wire LL arranged in the display panel 10a according to the second embodiment (see FIGS. 9 and 10). Further, the connection wire LL arranged at the outermost based on the center of the first pad PAD1 may be arranged like the connection wire LL arranged in the display panel 10 according to the first embodiment (see FIGS. 3 and 4). Accordingly, each of the connection wires LL may be arranged differently in cross-section based on its position on the plane, so that the resistance difference between the connection wires LL may be reduced or minimized.

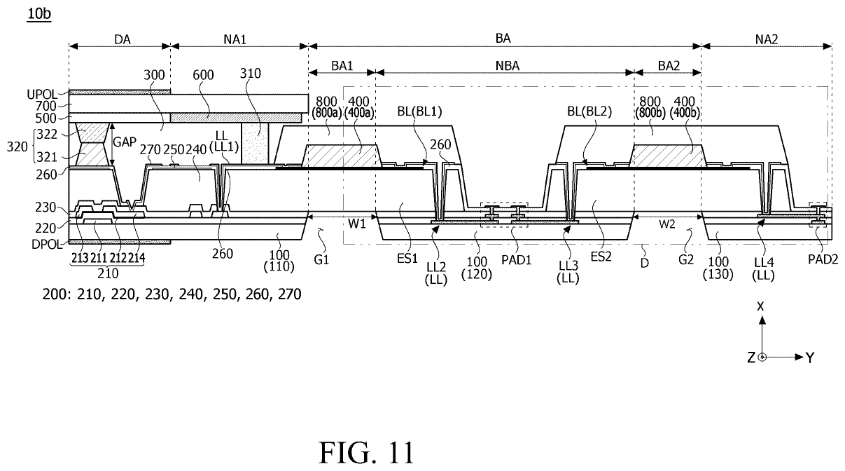

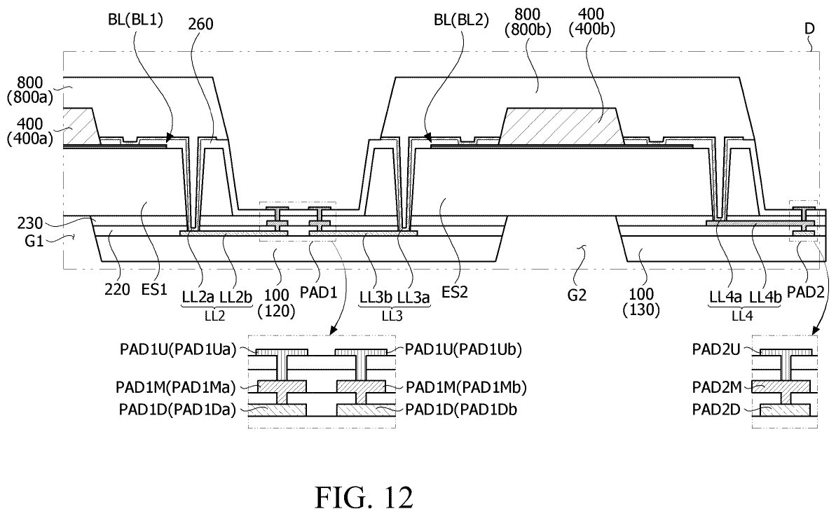

FIG. 11 is a view illustrating one embodiment of connection wire arranged in the display panel according to the embodiment of the present specification. FIG. 12 is an enlarged view of area D in FIG. 11. FIGS. 11 and 12 may be diagrams illustrating a third embodiment of a connection relationship of the first pad PAD1, the second pad PAD2, and the connection wire LL arranged in the display panel according to the embodiment of the present specification, but are not necessarily limited thereto. For example, the connection wire of the first embodiment (see FIGS. 3 and 4), the connection wire of the second embodiment (see FIGS. 9 and 10), and the connection wire of the third embodiment (see FIGS. 11 and 12) of the connection relationship of the first pad PAD1, the second pad PAD2 and the connection wire LL may all be arranged in one display panel. Here, FIG. 11 may be a diagram illustrating the connection wire arranged at the first distance D1 based on the lines I-I′.

In the display panel 10b shown in FIGS. 11 and 12, the second part LL2b of the second connection wire LL2, and the fourth part LL3b of the third connection wire LL3 may be located on the substrate 100. And, the sixth part LL4b of the fourth connection wire LL4 may be located on the gate insulating layer 220.

In describing the display panel 10b shown in FIGS. 11 and 12, the substantially identical components of the display panel 10 according to the first embodiment and the display panel 10a according to the second embodiment may be indicated by the same reference numerals, so that a detailed description thereof may be omitted or simplified.

Referring now to FIGS. 11 and 12, the display panel 10b includes the substrate 100 including the first area 110, the second area 120 and the third area 130 spaced apart from each other by the first groove G1 and the second groove G2, the circuit layer 200 arranged on the substrate 100, the liquid crystal layer 300 arranged on the circuit layer 200, the first pad PAD1 arranged on the second area 120, the second pad PAD2 arranged on the third area 130, and the plurality of connection wires LL and the plurality of bending wires BL. Further, the display panel 10b may include the first anti-etching layer ES1, the second anti-etching layer ES2, the sealant 310, the column 320, the pattern layer 400, the color filter layer 500, the black matrix 600, the second substrate 700, the lower polarization layer DPOL and the upper polarization layer UPOL, the protective layer 800, and the coating layer 900.

The second connection wire LL2 arranged on the display panel 10b may include the first part LL2a and the second part LL2b electrically connected through the third contact hole CH3. The second part LL2b may be electrically connected with the inner lower pad layer PAD1Da of the first lower pad layer PAD1D of the first pad PAD1. Here, the third contact hole CH3 may be a contact hole penetrating the gate insulating layer 220, the first interlayer dielectric layer 230, the first anti-etching layer ES1, and the second interlayer dielectric layer 260.

The third connection wire LL3 arranged on the display panel 10b may include the third part LL3a and the fourth part LL3b electrically connected through the fourth contact hole CH4. The fourth part LL3b may be electrically connected with the outer lower pad layer PAD1Db of the first lower pad layer PAD1D of the first pad PAD1. Here, the fourth contact hole CH4 may be a contact hole penetrating the gate insulating layer 220, the first interlayer dielectric layer 230, the second anti-etching layer ES2, and the second interlayer dielectric layer 260.

The fourth connection wire LL4 arranged in the display panel 10b may include the fifth part LL4a and the sixth part LL4b electrically connected through the seventh contact hole CH7. The sixth part LL4b may be electrically connected with the second intermediate pad layer PAD2M of the second pad PAD2. Here, the seventh contact hole CH7 may be a contact hole penetrating the first interlayer dielectric layer 230, the second anti-etching layer ES2, and the second interlayer dielectric layer 260.

Thus, the connection wire LL of the display panel 10b according to the third embodiment may have a shorter length on the plane than the connection wire LL of the display panel 10 according to the first embodiment, but may have a longer length in cross-section than the connection wire LL of the display panel 10 according to the first embodiment. Accordingly, the length of the connection wire LL of the display panel 10b according to the third embodiment and the connection wire LL of the display panel 10 according to the first embodiment may be substantially the same, but is not necessarily limited thereto. For example, the length of the connection wire LL of the display panel 10b according to the third embodiment and the connection wire LL of the display panel 10 according to the first embodiment may be somewhat different, but the resistance of the connection wire LL may be adjusted through a combination of materials used in the connection wire LL.

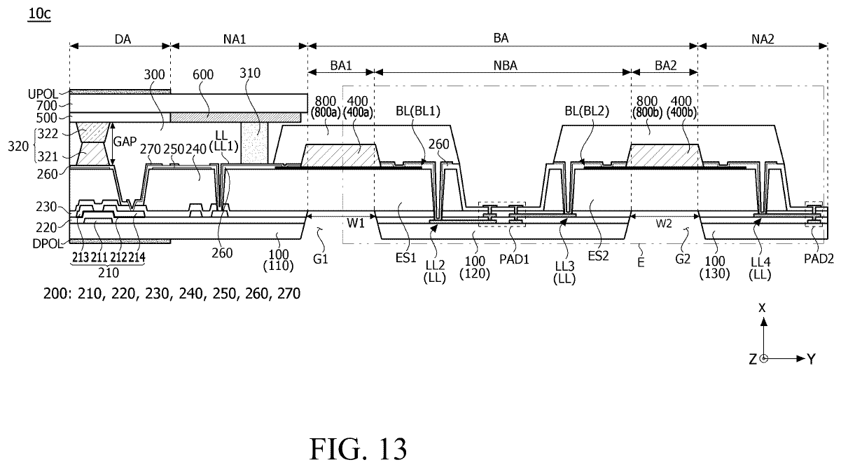

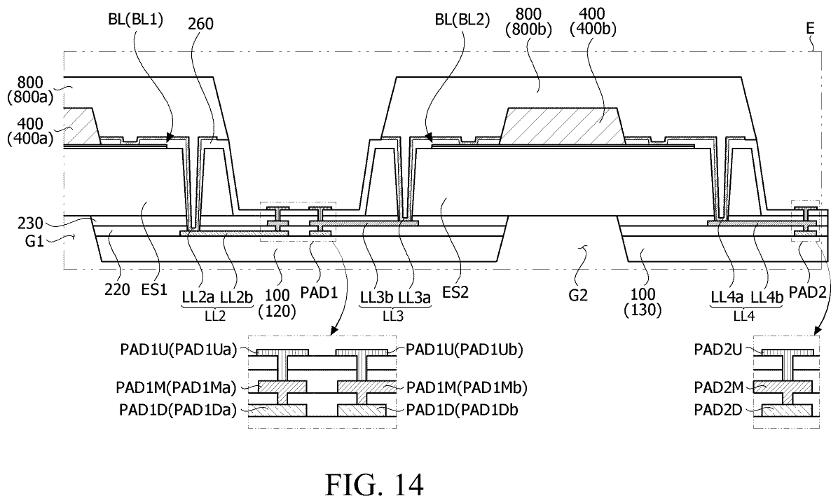

FIG. 13 is a view illustrating one embodiment of connection wire arranged in the display panel according to the embodiment of the present specification. FIG. 14 is an enlarged view of area E in FIG. 13. FIGS. 13 and 14 may be diagrams illustrating a fourth embodiment of a connection relationship of the first pad PAD1, the second pad PAD2, and the connection wire LL arranged in the display panel according to the embodiment of the present specification, but are not necessarily limited thereto. For example, the connection wire of the first embodiment (see FIGS. 3 and 4 (A and B)), the connection wire of the second embodiment (see FIGS. 9 and 10), the connection wire of the third embodiment (see FIGS. 11 and 12), and the connection wire of the fourth embodiment (see FIGS. 13 and 14) of the connection relationship of the first pad PAD1, the second pad PAD2 and the connection wire LL may all be arranged on one display panel. Here, FIG. 13 may be a diagram illustrating the connection wire arranged at the second distance D2 based on the lines I-I′. And, the second distance D2 may be larger than the first distance D1.

In the display panel 10c shown in FIGS. 13 and 14, the second part LL2b of the second connection wire LL2 may be located on the substrate 100. And, the fourth part LL3b of the third connection wire LL3 and the sixth part LL4b of the fourth connection wire LL4 may be located on the gate insulating layer 220.

In describing the display panel 10c shown in FIGS. 13 and 14, the substantially identical components of the display panel 10 according to the first embodiment to the display panel 10b according to the third embodiment may be indicated by the same reference numerals, so that a detailed description thereof may be omitted or simplified.

Referring now to FIGS. 13 and 14, the display panel 10c includes the substrate 100 including the first area 110, the second area 120 and the third area 130 spaced apart from each other by the first groove G1 and the second groove G2, the circuit layer 200 arranged on the substrate 100, the liquid crystal layer 300 arranged on the circuit layer 200, the first pad PAD1 arranged on the second area 120, the second pad PAD2 arranged on the third area 130, and the plurality of connection wires LL and the plurality of bending wires BL. Further, the display panel 10c may include the first anti-etching layer ES1, the second anti-etching layer ES2, the sealant 310, the column 320, the pattern layer 400, the color filter layer 500, the black matrix 600, the second substrate 700, the lower polarization layer DPOL and the upper polarization layer UPOL, the protective layer 800, and the coating layer 900.

The second connection wire LL2 arranged in the display panel 10c may include the first part LL2a and the second part LL2b electrically connected through the third contact hole CH3. The second part LL2b may be electrically connected with the inner lower pad layer PAD1Da of the first lower pad layer PAD1D of the first pad PAD1. Here, the third contact hole CH3 may be a contact hole penetrating the gate insulating layer 220, the first interlayer dielectric layer 230, the first anti-etching layer ES1, and the second interlayer dielectric layer 260.

The third connection wire LL3 arranged in the display panel 10c may include the third part LL3a and the fourth part LL3b electrically connected through the fourth contact hole CH4. The fourth part LL3b may be electrically connected with the outer lower pad layer PAD1Db of the first lower pad layer PAD1D of the first pad PAD1. Here, the fourth contact hole CH4 may be a contact hole penetrating the first interlayer dielectric layer 230, the second anti-etching layer ES2, and the second interlayer dielectric layer 260.

The fourth connection wire LL4 arranged in the display panel 10c may include the fifth part LL4a and the sixth part LL4b electrically connected through the seventh contact hole CH7. The sixth part LL4b may be electrically connected with the second intermediate pad layer PAD2M of the second pad PAD2. Here, the seventh contact hole CH7 may be a contact hole penetrating the first interlayer dielectric layer 230, the second anti-etching layer ES2, and the second interlayer dielectric layer 260.

Thus, the connection wire LL of the display panel 10c according to the fourth embodiment may have a shorter length on the plane than the connection wire LL of the display panel 10 according to the first embodiment, but may have a longer length in cross-section than the connection wire LL of the display panel 10 according to the first embodiment. In this case, the connection wire LL of the display panel 10c according to the fourth embodiment may have a longer length on the plane than the connection wire LL of the display panel 10b according to the third embodiment, but may have a shorter length in cross-section than the connection wire LL of the display panel 10b according to the third embodiment. Accordingly, the length of the connection wire LL of the display panel 10c according to the fourth embodiment may be substantially the same as the length of the connection wire LL of the display panel 10 according to the first embodiment or the length of the connection wire LL of the display panel 10b according to the third embodiment, but is not necessarily limited thereto.

The length of the connection wire LL of the display panel 10b according to the third embodiment may be somewhat different from the length of the connection wire LL of the display panel 10 according to the first embodiment and/or the connection wire LL of the display panel 10c according to the fourth embodiment. In this case, by adjusting the material applied to each part of the connection wires LL of the display panel 10b according to the third embodiment, the resistance difference for each of the plurality of connection wires LL may be reduced or minimized.

The display device according to the embodiment of the present specification may reduce or minimize a resistance difference for each of the plurality of connection wires LL through a combination of the arrangement position and material of the second part LL2b, the arrangement position and material of the fourth part LL3b and the arrangement position and material of the sixth part LL4b. For example, the resistance of the connection wires LL connected to the center side of the first pad PAD1 and the resistance of the connection wires LL arranged to be spaced apart from the center side of the first pad PAD1 may be adjusted by the above combination. For example, the second part LL2b, the fourth part LL3b, and the sixth part LL4b may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof, so that the resistance of each of the second part LL2b, the fourth part LL3b, and the sixth part LL4b may be adjusted by the material.

Since the arrangement relationship of the connection wire shown in FIGS. 2, 3, and 9 to 14 represents one embodiment of the arrangement relationship of the connection wire, a display device according to the embodiment of the present specification is not limited to the arrangement relationship of the connection wire shown in the drawings. For example, the display device according to the embodiment of the present specification may implement various embodiments of the connection wire LL other than the connection wire LL shown in the drawings by combining the arrangement position and material of the second part LL2b, the arrangement position and material of the fourth part LL3b, and the arrangement position and material of the sixth part LL4b.

The display device according to one or more embodiments of the present specification may be described as follows.

A display device according to one or more embodiments of the present specification may include a substrate including a first area, a second area and a third area spaced apart from each other by a first groove and a second groove; a circuit layer arranged on the first area and including a transistor; a first pad arranged on the second area; a second pad arranged on the third area; and a plurality of connection wires and a plurality of bending wires connecting the circuit layer, the first pad and the second pad. A chip may be arranged on the first pad.

The display device according to one or more embodiments of the present specification may further include a liquid crystal layer arranged on the circuit layer.

The display device according to one or more embodiments of the present specification may further include a first anti-etching layer arranged over the first groove and a second anti-etching layer arranged over the second groove.

According to one or more embodiments of the present specification, the circuit layer may include a planarization layer extending from the first area to the second area. A portion of the planarization layer may be provided as the first anti-etching layer. The planarization layer may include an organic material.

According to one or more embodiments of the present specification, the plurality of bending wires may include a first bending wire and a second bending wire. The first bending wire may be arranged on a first anti-etching layer arranged over the first groove, and the second bending wire may be arranged on a second anti-etching layer arranged over the second groove.

The display device according to one or more embodiments of the present specification may further include a first pattern layer arranged on the first bending wire to overlap with the first groove and a second pattern layer arranged on the second bending wire to overlap with the second groove.

The display device according to one or more embodiments of the present specification may further include a first protective layer arranged on the first pattern layer and a second protective layer arranged on the second pattern layer.

The display device according to one or more embodiments of the present specification may further include a first coating layer arranged in the first groove and a second coating layer arranged in the second groove.

According to one or more embodiments of the present specification, the plurality of connection wires may include a first connection wire connecting the circuit layer and the first bending wire, a second connection wire connecting the first bending wire and the first pad, a third connection wire connecting the first pad and the second bending wire, and a fourth connection wire connecting the second bending wire and the second pad.

According to one or more embodiments of the present specification, the first pad may include a first lower pad layer arranged in the second area, a first intermediate pad layer arranged on the first lower pad layer, and a first upper pad layer arranged on the first intermediate pad layer. The second connection wire may be connected to either the first lower pad layer or the first intermediate pad layer.

According to one or more embodiments of the present specification, the second connection wire may include a first part and a second part connected to the first part. The second part may be connected to either the first lower pad layer or the first intermediate pad layer.

According to one or more embodiments of the present specification, the first pad may include a first lower pad layer arranged in the second area, a first intermediate pad layer arranged on the first lower pad layer, and a first upper pad layer arranged on the first intermediate pad layer. The third connection wire may be connected to either the first lower pad layer or the first intermediate pad layer.

According to one or more embodiments of the present specification, the third connection wire may include a third part and a fourth part connected to the third part. The fourth part may be connected to either the first lower pad layer or the first intermediate pad layer.

According to one or more embodiments of the present specification, the second pad may include a second lower pad layer arranged in the third area, a second intermediate pad layer arranged on the second lower pad layer, and a second upper pad layer arranged on the second intermediate pad layer. The fourth connection wire may be connected to either the second lower pad layer or the second intermediate pad layer.

According to one or more embodiments of the present specification, the fourth connection wire may include a fifth part and a sixth part connected to the fifth part. The sixth part may be connected to either the second lower pad layer or the second intermediate pad layer.

According to one or more embodiments of the present specification, the first pad may include a first lower pad layer arranged in the second area, a first intermediate pad layer arranged on the first lower pad layer, and a first upper pad layer arranged on the first intermediate pad layer. The first lower pad layer, the first intermediate pad layer, and the first upper pad layer may be made of different materials.

According to one or more embodiments of the present specification, the second pad may include a second lower pad layer arranged in the third area, a second intermediate pad layer arranged on the second lower pad layer, and a second upper pad layer arranged on the second intermediate pad layer. The second lower pad layer, the second intermediate pad layer, and the second upper pad layer may be made of different materials.

According to one or more embodiments of the present specification, the bending wire may include a first layer and a second layer, wherein the first layer and the material of the second layer may be made of different materials.

According to one or more embodiments of the present specification, some areas of the connection wire may be arranged on the bending wire.

According to one or more embodiments of the present specification, a first side surface of the first area, second and third side surfaces of the second area, and a fourth side surface of the third area may be an inclined surface having a predetermined angle.

According to one or more embodiments of the present specification, the first substrate and the second substrate may include a glass material.

According to one or more embodiments of the present specification, the circuit layer may include a planarization layer and a first electrode arranged on the planarization layer, the bending wire may include a first layer and a second layer, and at least one of the first layer and the second layer may include the same metal layer as the first electrode.

The display device according to one or more embodiments of the present specification may further include a liquid crystal layer arranged on the circuit layer, a backlight unit emitting light toward the liquid crystal layer and a case surrounding the backlight unit, and a thermal conductive member arranged between the second area and the case, wherein the case may include a metal material.

According to one or more embodiments of the present specification, the plurality of bending wires may include a first bending wire and a second bending wire, wherein the center of curvature of the first bending wire and the center of curvature of the second bending wire may be different.

A display device according to one or more embodiments of the present specification may include a display area in which an image is implemented, and a non-display area surrounding at least a portion of the display area, wherein the non-display area may include a first non-display area, a bending area including a groove, and a second non-display area. In the bending area, a first pad on which a chip is arranged may be arranged, and in the second non-display area overlapping with the first non-display area by bending of the bending area, a second pad to which a circuit board is connected may be arranged.

A display device according to one or more embodiments of the present specification may include a display area in which an image is implemented, and a non-display area surrounding at least a portion of the display area, wherein the non-display area includes a first non-display area, a bending area including two grooves, and a second non-display area, wherein a first pad, where a chip is arranged, is arranged between the two grooves, and wherein a second pad, to which a circuit board is connected, is arranged in the second non-display area overlapping with the first non-display area by bending of the bending area.

The display device according to one or more embodiments of the present specification may further include an anti-etching layer arranged over the groove, a bending wire arranged on the anti-etching layer, a pattern layer arranged on the bending wire, and a protective layer arranged on the pattern layer, wherein a portion of the protective layer may be arranged in the inside of a groove concavely formed in the anti-etching layer.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate comprising a first area, a second area and a third area spaced apart from each other by a first groove and a second groove;
a circuit layer arranged in the first area, wherein the circuit layer comprises a transistor;
a first pad arranged in the second area;
a second pad arranged in the third area; and
a plurality of connection wires and a plurality of bending wires connecting the circuit layer, the first pad, and the second pad,
wherein a chip is arranged on the first pad.

2. The display device according to claim 1, further comprising:
a first anti-etching layer arranged over the first groove and a second anti-etching layer arranged over the second groove.

3. The display device according to claim 2, wherein the circuit layer comprises a planarization layer extending from the first area to the second area, and
wherein a portion of the planarization layer is provided as the first anti-etching layer.

4. The display device according to claim 1, wherein:
the plurality of bending wires comprises a first bending wire and a second bending wire,
the first bending wire is arranged on a first anti-etching layer arranged over the first groove, and
the second bending wire is arranged on a second anti-etching layer arranged over the second groove.

5. The display device according to claim 4, further comprising:
a first pattern layer arranged on the first bending wire to overlap with the first groove and a second pattern layer arranged on the second bending wire to overlap with the second groove.

6. The display device according to claim 5, further comprising:
a first protective layer arranged on the first pattern layer and a second protective layer arranged on the second pattern layer.

7. The display device according to claim 6, further comprising:
a first coating layer arranged in the first groove and a second coating layer arranged in the second groove.

8. The display device according to claim 4, wherein the plurality of connection wires comprises:
a first connection wire connecting the circuit layer and the first bending wire;
a second connection wire connecting the first bending wire and the first pad;
a third connection wire connecting the first pad and the second bending wire; and
a fourth connection wire connecting the second bending wire and the second pad.

9. The display device according to claim 8, wherein the first pad comprises a first lower pad layer arranged in the second area, a first intermediate pad layer arranged on the first lower pad layer, and a first upper pad layer arranged on the first intermediate pad layer, and
wherein the second connection wire is connected to either the first lower pad layer or the first intermediate pad layer.

10. The display device according to claim 9, wherein the second connection wire comprises a first part and a second part connected to the first part, and
wherein the second part is connected to either the first lower pad layer or the first intermediate pad layer.

11. The display device according to claim 8, wherein the first pad comprises a first lower pad layer arranged in the second area, a first intermediate pad layer arranged on the first lower pad layer, and a first upper pad layer arranged on the first intermediate pad layer, and
wherein the third connection wire is connected to either the first lower pad layer or the first intermediate pad layer.

12. The display device according to claim 11, wherein the third connection wire comprises a third part and a fourth part connected to the third part, and
wherein the fourth part is connected to either the first lower pad layer or the first intermediate pad layer.

13. The display device according to claim 8, wherein the second pad comprises a second lower pad layer arranged in the third area, a second intermediate pad layer arranged on the second lower pad layer, and a second upper pad layer arranged on the second intermediate pad layer, and
wherein the fourth connection wire is connected to either the second lower pad layer or the second intermediate pad layer.

14. The display device according to claim 13, wherein the fourth connection wire comprises a fifth part and a sixth part connected to the fifth part, and
wherein the sixth part is connected to either the second lower pad layer or the second intermediate pad layer.

15. The display device according to claim 1, wherein the first pad comprises a first lower pad layer arranged in the second area, a first intermediate pad layer arranged on the first lower pad layer, and a first upper pad layer arranged on the first intermediate pad layer, and
wherein the first lower pad layer, the first intermediate pad layer, and the first upper pad layer are made of different materials.

16. The display device according to claim 1, wherein the second pad comprises a second lower pad layer arranged in the third area, a second intermediate pad layer arranged on the second lower pad layer, and a second upper pad layer arranged on the second intermediate pad layer, and
wherein the second lower pad layer, the second intermediate pad layer, and the second upper pad layer are made of different materials.

17. The display device according to claim 1, wherein each of the plurality of bending wires comprises a first layer and a second layer, and
wherein the first layer and the second layer are made of different materials.

18. The display device according to claim 1, wherein the circuit layer comprises a planarization layer and a first electrode arranged on the planarization layer,
wherein each of the plurality of bending wires comprises a first layer and a second layer, and
wherein at least one of the first layer and the second layer comprises same metal layer as the first electrode.

19. The display device according to claim 1, further comprising:
a liquid crystal layer arranged on the circuit layer;
a backlight unit configured to emit light toward the liquid crystal layer and a case surrounding the backlight unit; and
a thermal conductive member arranged between the second area and the case,
wherein the case comprises a metal material.

20. The display device according to claim 1, wherein the plurality of bending wires comprises a first bending wire and a second bending wire, and
wherein a center of curvature of the first bending wire and a center of curvature of the second bending wire are different.

21. A display device comprising:
a display area in which an image is implemented;
a non-display area surrounding at least a portion of the display area,
wherein the non-display area comprises a first non-display area, a bending area comprising a groove, and a second non-display area;
a first pad, wherein a chip is arranged, and wherein the first pad is arranged in the bending area; and
a second pad, to which a circuit board is connected, wherein the second pad is arranged in the second non-display area overlapping with the first non-display area.

22. The display device according to claim 21, further comprising:
an anti-etching layer arranged over the groove;
a bending wire arranged on the anti-etching layer;
a pattern layer arranged on the bending wire; and
a protective layer arranged on the pattern layer,
wherein a portion of the protective layer is arranged in an inside of the groove concavely formed in the anti-etching layer.
